(19) United States
(12) Patent Application Publication
(10) Pub. No.: US 2026/0271453 A1
(43) Pub. Date: Sep. 10, 2026

(54) DISPLAY DEVICE INCLUDING INORGANIC LED, ELECTRONIC DEVICE INCLUDING THE DISPLAY DEVICE, AND METHOD FOR MANUFACTURING THE DISPLAY DEVICE

(71) Applicant: SAMSUNG DISPLAY CO., LTD., YONGIN-SI (KR)

(72) Inventor: Yuk Hyun NAM, Yongin-si (KR)

(21) Appl. No.: 19/335,839

(22) Filed: Sep. 22, 2025

(30) Foreign Application Priority Data
Mar. 5, 2025 (KR) 10-2025-0028471
May 13, 2025 (KR) 10-2025-0061942

(51) Int. Cl. H10H 29/49; H10H 20/812; H10H 29/01

(52) U.S. Cl. CPC H10H 29/49; H10H 20/812; H10H 29/032; H10H 29/0364

(57) ABSTRACT

A display device includes a substrate including a plurality of light emission areas, a first pixel electrode disposed in the first light emission area, a second pixel electrode disposed in the second light emission area, alignment electrodes disposed in the third light emission area, and first and second light emitting structures disposed on the first and second pixel electrodes, respectively. Each of the first and second light emitting structures includes a quantum dot light emitting layer. The display device further includes an inorganic light emitting diode disposed on the alignment electrodes, a common electrode disposed on the first and second light emitting structures, and a first contact electrode and a second contact electrode disposed on the inorganic light emitting diode. The first contact electrode contacts one end portion of the inorganic light emitting diode and the second contact electrode contacts other end portion of the inorganic light emitting diode.

### CROSS-REFERENCE TO RELATED APPLICATIONS

This U.S. non-provisional patent application claims priority under 35 U.S.C. § 119 to Korean Patent Application Nos. 10-2025-0028471 filed on Mar. 5, 2025 and 10-2025-0061942 filed on May 13, 2025, in the Korean Intellectual Property Office, the entire contents of which are herein incorporated by reference.

### TECHNICAL FIELD

Embodiments of the present disclosure relate to a display device and, more particularly to, a display device including an inorganic light emitting diode, an electronic device including the display device, and a method for manufacturing the display device.

### DISCUSSION OF THE RELATED ART

With the advancement of the digital technology, the demand for a display device capable of displaying images in various forms have increased. For example, the display device may be implemented in various electronic devices such as a smart phone, a digital camera, a laptop computer, a navigator, and a smart television.

The display device may be a flat panel display device such as a liquid crystal display device, a field emission display device, or a light emitting display device. The light emitting display device may include an organic light emitting display device including an organic light emitting element. The light emitting display device may include an inorganic light emitting display device including an inorganic light emitting element such as a quantum dot light emitting element.

Among the light emitting display devices, the display device including a quantum dot is under active development, and efforts are made to improve efficiency of such display device.

### SUMMARY

According to an aspect of the present disclosure, a display device may include substrate including a first light emission area, a second light emission area, and a third light emission area, a first pixel electrode disposed in the first light emission area, a second pixel electrode disposed in the second light emission area, alignment electrodes disposed in the third light emission are, first and second light emitting structures disposed on the first and second pixel electrodes, respectively, wherein each of the first and second light emitting structures includes a quantum dot light emitting layer, an inorganic light emitting diode disposed on the alignment electrodes, a common electrode disposed on the first and second light emitting structures, and a first contact electrode and a second contact electrode disposed on the inorganic light emitting diode. The first contact electrode may contact one end portion of the inorganic light emitting diode and the second contact electrode may contact the other end portion of the inorganic light emitting diode.

In an embodiment, the first pixel electrode, the first light emitting structure, and the common electrode may be disposed in the first light emission area. The second pixel electrode, the second light emitting structure, and the common electrode may be disposed in the second light emission area.

In an embodiment, the common electrode may be continuously extended and disposed in the first light emission area and the second light emission area.

In an embodiment, the first light emission area may emit red light, the second light emission area may emit green light, and the third light emission area may emit blue light.

In an embodiment, the display device may further include a first insulating layer disposed on the alignment electrodes. The alignment electrodes may include first and second alignment electrodes spaced apart from each other, and the inorganic light emitting diode may be arranged on the first insulating layer and may overlap at least a portion of the first alignment electrode and a portion of the second alignment electrode.

In an embodiment, the display device may further include a second insulating layer disposed on the inorganic light emitting diode. The second insulating layer may have an island-shaped pattern.

In an embodiment, the first insulating layer and the second insulating layer may overlap the third light emission area and might not overlap the first light emission area and the second light emission area.

In an embodiment, the first insulating layer may include a first area overlapping the inorganic light emitting diode and a second area adjacent to the first area, and a thickness of the first insulating layer in the first area may be smaller than a thickness of the first insulating layer in the second area.

In an embodiment, the first pixel electrode, the second pixel electrode, and the alignment electrodes may be arranged at a same layer, and include the same material.

In an embodiment, the common electrode, the first contact electrode, and the second contact electrode may include the same material.

According to an aspect of the present disclosure, a method for manufacturing a display device include forming a first pixel electrode, a second pixel electrode, and alignment electrodes on a substrate, forming a first insulating layer on the alignment electrodes, forming a bank layer on the first insulating layer, the first pixel electrode, and the second pixel electrode to partition the first pixel electrode, the second pixel electrode and the alignment electrodes, forming an inorganic light emitting diode on the alignment electrodes, forming a second insulating layer on the inorganic light emitting diode, forming a first light emitting structure on the first pixel electrode and forming a second light emitting structure on the second pixel electrode, and forming a common electrode on the first light emitting structure and the second light emitting structure, and at the simultaneously forming a first contact electrode contacting one end of the inorganic light emitting diode and a second contact electrode contacting the other end of the inorganic light emitting diode on the second insulating layer.

In an embodiment, the first pixel electrode, the second pixel electrode, and the alignment electrodes may be formed simultaneously.

In an embodiment, the first insulating layer may be formed to include a first area and a second area thicker than the first area by using a halftone mask.

In an embodiment, each of the inorganic light emitting diode, the first light emitting structure, and the second light emitting structure may be formed using an inkjet printing process.

In an embodiment, forming the second insulating layer may include forming contact holes to expose the alignment electrodes by etching a portion of the first insulating layer.

In an embodiment, the first contact electrode and the second contact electrode may connect to the alignment electrodes through the contact holes.

According to an aspect of the present disclosure, an electronic device includes display device, a memory having a stored application for operating the electronic device including the display device, a processor configured to execute the application stored in the memory, and a power module configured to supply power to the display device, the memory, and the processor. The display device may include a substrate including a first light emission area, a second light emission area, and a third light emission area, a first pixel electrode disposed in the first light emission area and a second pixel electrode disposed in the second light emission area, alignment electrodes disposed in the third light emission are, first and second light emitting structures disposed on the first pixel electrode and the second pixel electrode, respectively, each of the first and second light emitting structures includes a quantum dot light emitting layer, an inorganic light emitting diode disposed on the alignment electrodes, a common electrode disposed on the first and second light emitting structures, and a first contact electrode and a second contact electrode disposed on the inorganic light emitting diode. The first contact electrode may contact one end portion of the inorganic light emitting diode and the second contact electrode may contact the other end portion of the inorganic light emitting diode.

In an embodiment, the first pixel electrode, the second pixel electrode, and the alignment electrodes may be disposed at a same layer, and may include the same material.

In an embodiment, the common electrode, the first contact electrode, and the second contact electrode may include the same material.

In an embodiment, the first light emission area may emit red light, the second light emission area may emit green light, and the third light emission area may emit blue light.

In the display device according to one embodiment, a first light emission area for emitting red light and a second light emission area for emitting green light may include light emitting structures including a quantum dot light emitting layer, and a third light emission area for emitting blue light may include an inorganic light emitting diode. Accordingly, lifespans of red light, green light and blue light may be adjusted to the same level, and display quality of the display device may be improved.

The method for manufacturing the display device according to one embodiment may reduce material costs by performing an inkjet printing process for light emitting elements of respective light emission areas. In addition, a common electrode and contact electrodes may be formed simultaneously, so that a process may be simplified, thereby increasing productivity.

### BRIEF DESCRIPTION OF THE DRAWINGS

The above and other aspects and features of the present disclosure ware apparent from the detailed description of the embodiments with reference to the attached drawings, in which:

FIG. 1 is a block diagram illustrating an electronic device according to an embodiment;

FIG. 2 illustrates schematic diagrams of electronic devices according to various embodiments;

FIG. 3 is a schematic plan view illustrating a display device according to an embodiment;

FIG. 4 is a plan view illustrating a plurality of subpixels of a display device according to an embodiment;

FIG. 5 is a cross-sectional view taken along a cutting line Q1-Q1′ of FIG. 4;

FIG. 6 is an enlarged cross-sectional view illustrating a light emitting element layer of a first light emission area of a display device shown in FIG. 5;

FIG. 7 is a schematic plan view illustrating a third light emission area of FIG. 4;

FIG. 8 is a cross-sectional view taken along a cutting line Q2-Q2′ of FIG. 7;

FIG. 9 is a schematic view illustrating a third light emitting element according to an embodiment; and

FIGS. 10, 11, 12, 13, 14, 15, 16, 17, 18, 19, 20, and 21 are views for each process illustrating a method for manufacturing a display device according to an embodiment.

### DETAILED DESCRIPTION

The present invention is described fully hereinafter with reference to the accompanying drawings, in which preferred embodiments of the invention are shown. However, embodiments of the present disclosure may be embodied in different forms and should not necessarily be construed as limited to the embodiments set forth herein. Rather, these embodiments are provided so that the present disclosure is thorough and complete, and fully conveys the scope of the invention to those skilled in the art.

It will also be understood that when a layer is referred to as being “on” another layer or substrate, it can be directly on the other layer or substrate, or intervening layers may also be present. For example, intervening regions, layers, or portion may be present between the regions, layers, or portions, respectively.

The same reference numbers indicate the same components throughout the disclosure and the drawings. For example, while each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like. As used herein, the term “and/or” includes any and all combinations of one or more of the associated listed elements.

It will be understood that, although the terms “first,” “second,” etc. may be used to describe various elements, these elements should not necessarily be limited by these terms. These terms are used to distinguish one element from another element. For example, a first element could be termed a second element without departing from the teachings of the present invention. Similarly, the second element could also be termed the first element.

Each of the features of the various embodiments of the present disclosure may be combined or combined with each other, in part or in whole, and technically various interlocking and driving are possible. Each embodiment may be implemented independently of each other or may be implemented together in an association.

Hereinafter, detailed embodiments are described with reference to the accompanying drawings.

Embodiments of the present disclosure provide a display device including a plurality of light emission areas disposed on a substrate. The display device includes a first pixel electrode and a second pixel electrode disposed in a first light emission area and a second light emission area, respectively, and a quantum dot light emitting structure disposed in each pixel electrode. A third light emission area includes an inorganic light emitting diode, and is electrically coupled through first and second alignment electrodes disposed on the same layer as the pixel electrodes. A common electrode is disposed over the quantum dot light emitting structures, and first and second contact electrodes are disposed over the inorganic light emitting diode.

By integrating quantum dot light emitting structures and inorganic light emitting diodes into separate light emission areas of a single display substrate, embodiments of the present disclosure provide enhanced performance characteristics tailored to each subpixel. For example, the quantum dot structures offer high color purity for red and green emission, and the inorganic light emitting diode provides improved longevity and reliability for blue emission. This hybrid pixel architecture enables lifespan balancing across subpixels, reduces blue degradation artifacts, and improves overall display quality. Furthermore, forming the common electrode and contact electrodes simultaneously simplifies the manufacturing process and enhances production efficiency.

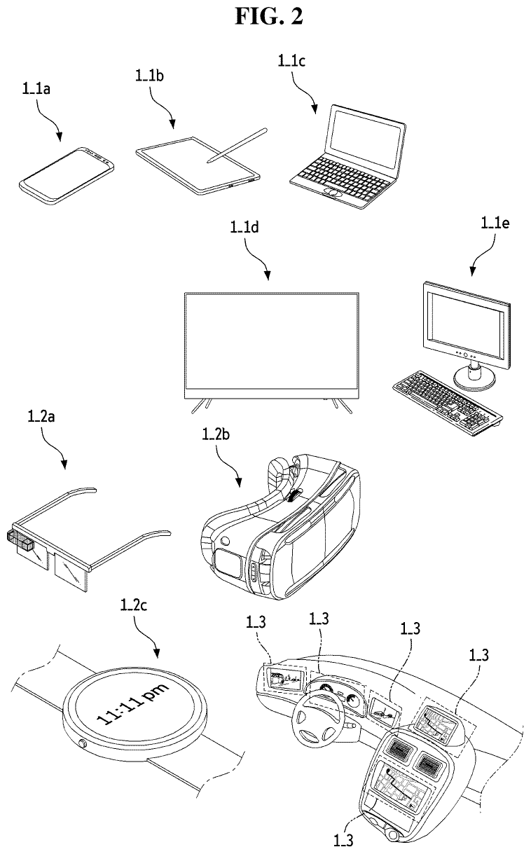

A display device, according to the embodiment of the present disclosure, may be applied to various electronic devices. The electronic device includes the display device, and may further include modules or devices having other additional functions in addition to the display device. In some embodiments, the electronic device ED may be implemented in various devices described with reference to FIG. 2

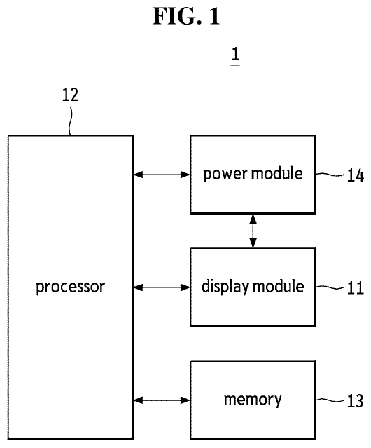

FIG. 1 is a block diagram illustrating an electronic device according to an embodiment. Referring to FIG. 1, an electronic device 1 may include a display module 11, a processor 12, a memory 13, and a power module 14.

The processor 12 may include at least one of a central processing unit (CPU), an application processor (AP), a graphics processing unit (GPU), a communication processor (CP), an image signal processor (ISP), or a controller. In some cases, the processor PR may control the overall operation of the electronic device ED, including driving the display module DM based on image and data signals stored in memory MR. The power module PM may supply and control electrical power provided to each of the functional components.

Data (or digital instructions) required for an operation of the processor 12 or the display module 11 may be stored in the memory 13. When the processor 12 executes an application stored in the memory 13, an image data signal and/or an input control signal is transmitted to the display module 11, and the display module 11 may process the received signal and output image information through a display screen.

The power module 14 may include a power supply module such as a power adapter or a battery device, and a power conversion module that converts a power source supplied by the power supply module into a power source for the operation of the electronic device 1.

At least one of the respective components of the above-described electronic device 1 may be included in the display device according to the above-described embodiments. Also, some of the individual modules functionally included in one module may be included in the display device, and remaining modules may be provided separately from the display device. For example, the display device includes a display panel 11, and the processor 12, the memory 13 and the power module 14 may be provided as other devices in the electronic device 1 not the display device.

FIG. 2 illustrates schematic diagrams of electronic devices according to various embodiments. For example, FIG. 2 shows a range of applicable form in which the inventive display device may be implemented. However, embodiments of the present disclosure are not necessarily limited thereto.

Referring to FIG. 2, various electronic devices may be implemented in image display devices, such as a smartphone 1_1a, a tablet computer 1_1b, a laptop computer 1_1c, a television (TV) 1_1d, and a desktop monitor 1_1e, In some cases, the electronic devices may be implemented in wearable electronic devices including display modules such as smart glasses 1_2a, a head-mounted display 1_2b, and a smart watch 1_2c. In some cases, the electronic devices may be implemented in a vehicle electronic device 1_3 including display modules such as a vehicle dashboard, a center fascia, a center information display (CID) arranged on the dashboard, and a room mirror display.

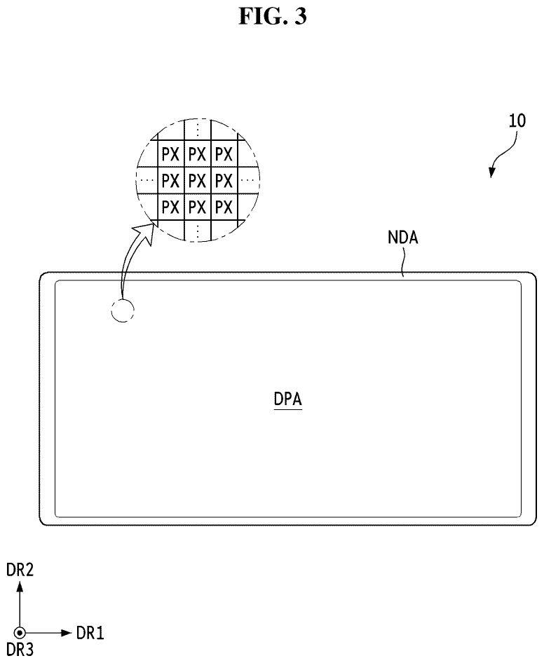

FIG. 3 is a schematic plan view illustrating a display device according to one embodiment. The example shown may include a display device 10 includes a plurality of pixels PX disposed on the display area DPA. The display area DPA may be surrounded by the non-display area NDA.

In the present disclosure, “upper”, “top”, and “upper surface” refer to an upper direction with respect to the display device 10. For example, the upper direction may be in the third direction DR3, and “lower”, “bottom”, and “lower surface” refer to the other direction opposite to the third direction DR3. Also, “left”, “right”, “upper” and “lower” refer to a direction when the display device 10 is viewed on a plane. For example, “right” refers to the first direction DR1, “left” refers to the direction opposite to the first direction DR1, “upper” refers to the second direction DR2, and “lower” refers to the direction opposite to the second direction DR2.

Referring to FIG. 3, the display device 10 may display a moving image (e.g., a video) or a still image. The display device 10 may refer to an electronic device that provides a display screen. For example, the display device 10 may include a television (TV), a laptop, a monitor, a billboard, Internet of Things (IoT), a mobile phone, a smartphone, a tablet PC, an electronic watch, a smart watch, a watch phone, a head-mounted display, a mobile communication terminal, an electronic diary, an electronic book, a Portable Multimedia Player (PMP), a navigator, a game console, a digital camera, and a camcorder.

The display device 10 may include a display panel that provides a display screen. Examples of the display panel may include an inorganic light emitting diode display panel, an organic light emitting display panel, a quantum dot light emitting display panel, a plasma display panel, and a field emission display panel. The following description describe an embodiment in which an inorganic light emitting display panel is used as an example of the display panel, but the present disclosure is not necessarily limited thereto. For example, another display panel may be applied to the display device 10 within the range in which the same technical concepts are applicable.

Various modifications may be made to a shape of the display device 10. The display device 10 may have a shape such as a rectangle of a long width, a rectangle of a long length, a square, a rectangle of round corners (vertexes), other polygons, and a circle. A shape of a display area DPA of the display device 10 may also be substantially similar to an overall shape of the display device 10. A rectangular display device 10 and display area DPA, in which a width is longer, is illustrated in FIG. 3. For example, the width of the display device may be measured along the first direction DR1. The second direction DR2 may cross the first direction DR1.

The display device 10 may include a display area DPA and a non-display area NDA. The display area DPA is an area in which a screen may be displayed, and the non-display area NDA is an area in which a screen is not displayed. The display area DPA may be referred to as an active area, and the non-display area NDA may be referred to as a non-active area. The display area DPA may generally occupy the central portion of the display device 10. However, embodiments are not necessarily limited thereto.

The display area DPA may include a plurality of pixels PX. The plurality of pixels PX may be arranged in a matrix direction. A shape of each pixel PX may be a rectangular or square shape on a plane, but is not necessarily limited thereto. The shape of each pixel PX may be a rhombus shape in which each side is inclined with respect to one direction. Each pixel PX may be alternately arranged in a stripe type or a PenTile™ type. Also, each of the pixels PX may include one or more light emitting elements for emitting light of a specific wavelength band to display a specific color. Each pixel PX may include a plurality of subpixels.

The non-display area NDA may be arranged in the vicinity of the display area DPA. The non-display area NDA may fully or partially surround the display area DPA. The display area DPA may be rectangular in shape, and the non-display area NDA may be adjacent to four sides of the display area DPA. For example, the non-display area NDA may surround the display area DPA. The non-display area NDA may be a bezel of the display device 10. Electrical lines or circuit drivers included in the display device 10 may be arranged in each of the non-display areas NDA, or external devices may be disposed in the non-display areas NDA of the display device 10.

Each pixel PX or each subpixel of the display device 10 includes a pixel driving circuit. Signal lines may apply a driving signal to each pixel driving circuit while passing through each pixel PX or its periphery. The pixel driving circuit may include a transistor and a capacitor. Various modifications may be made in the number of transistors and capacitors of each pixel driving circuit. According to an embodiment, each pixel PX or each subpixel of the display device 10 may have a 3T1C structure in which the pixel driving circuit includes three transistors and one capacitor, but the embodiment is not necessarily limited thereto. Various modified pixel structures such as a 2TIC structure, a 7TIC structure and a 6TIC structure may be applied to each pixel PX or each subpixel.

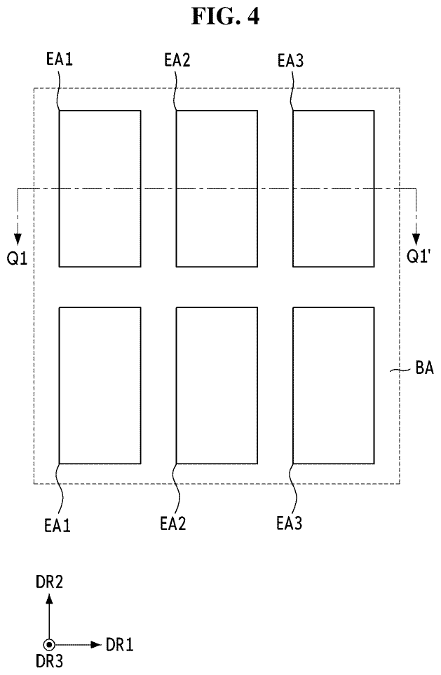

In an embodiment, the plurality of subpixels within each pixel PX may include red and green subpixels that use quantum dot-based light emitting structures and a blue subpixel that uses an inorganic light emitting diode. This hybrid arrangement enhances the display performance and lifespan uniformity among the color components of the display device 10. Further detail on this hybrid structure of the pixels is described with reference to FIGS. 4-8.

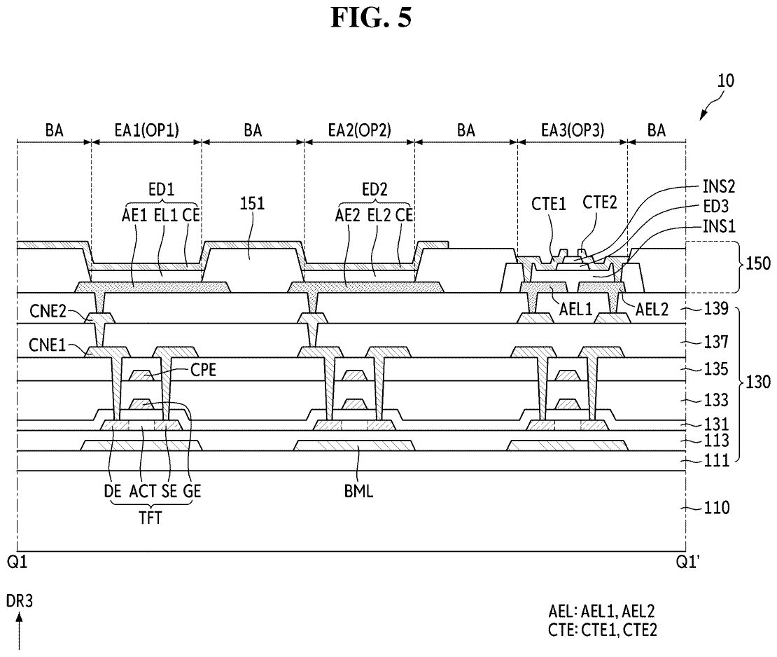

FIG. 4 is a plan view illustrating a plurality of subpixels of a display device according to an embodiment. Each of the subpixels may include a first light emission area EA1, a second light emission area EA2, and a third light emission area EA3, which correspond to different light emitting elements. A non-light emission area BA may separate adjacent light emission areas EA1, EA2 and EA3. A cross-sectional view along line Q1-Q1′ is illustrated in FIG. 5.

Referring to FIG. 4, the display device 10 may include a plurality of light emission areas EA1, EA2 and EA3 arranged in the display area DPA. The plurality of light emission areas EA1, EA2 and EA3 may include a first light emission area EA1, a second light emission area EA2, and a third light emission area EA3, which emit light of different colors. Each of the plurality of light emission areas EA1, EA2 and EA3 may emit red light, green light, or blue light, respectively. The color of light emitted from each of the light emission areas EA1, EA2 and EA3 may be different based on the type of light emitting elements arranged on a light emitting element layer (150 of FIG. 5) in each of the light emission areas EA1, EA2 and EA3. In an embodiment, the first light emission areas EA1 may emit red light, the second light emission areas EA2 may emit green light, and the third light emission areas EA3 may emit blue light.

A non-light emission area BA is an area surrounding each of the light emission areas EA1, EA2 and EA3, and may be an area through which light does not pass. The non-light emission area BA may serve to electrically and optically isolate adjacent subpixels and may include insulating regions or electrode separation zones. However, the embodiment is not necessarily limited thereto.

In some cases, the light emission areas EA1, EA2, and EA3 may be arranged along the first direction DR1 and second direction DR2 to form a two-dimensional subpixel array. In an embodiment, the first and second light emission areas EA1 and EA2 may include quantum dot-based light emitting structures, and the third light emission area EA3 may include an inorganic light emitting diode to enhance blue subpixel longevity. Further detail on the light emitting structures within the light emission areas EA1, EA2, and EA3 is described with reference to FIGS. 5-8.

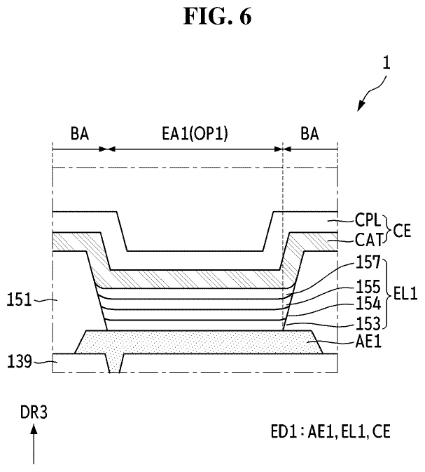

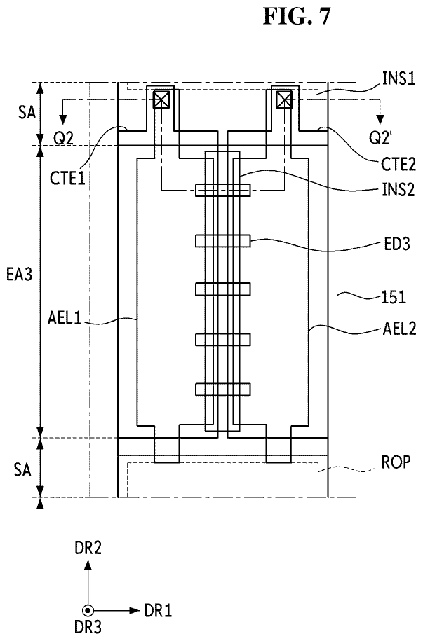

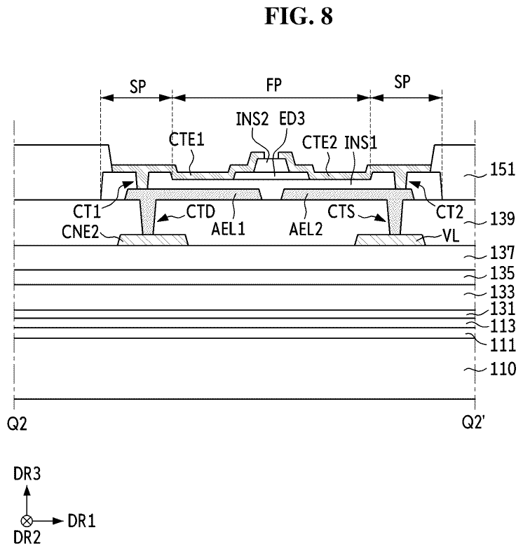

FIG. 5 is a cross-sectional view taken along a line Q1-Q1′ of FIG. 4. FIG. 6 is an enlarged cross-sectional view illustrating a light emitting element layer of a first light emission area of a display device shown in FIG. 5. FIG. 7 is a schematic plan view illustrating a third light emission area of FIG. 4. FIG. 8 is a cross-sectional view taken along a line Q2-Q2′ of FIG. 7.

Referring to FIG. 5, the display device 10 may include a substrate 110, a thin film transistor layer 130, and a light emitting element layer 150. In some cases, for example, the light emitting element layer 150 may include a plurality of pixel-specific structures, including a first light emitting element ED1, a second light emitting element ED2, and a third light emitting element ED3, corresponding to red subpixel, green subpixel, and blue subpixel, respectively.

The thin film transistor layer 130 may be disposed on a substrate 110. The thin film transistor layer 130 may include a first buffer layer 111, a lower metal layer BML, a second buffer layer 113, a thin film transistor TFT, a gate insulating layer 131, a first interlayer insulating layer 133, a capacitor electrode CPE, a second interlayer insulating layer 135, a first connection electrode CNE1, a first passivation layer 137, a second connection electrode CNE2, and a second passivation layer 139. In some cases, these layers may be sequentially stacked to form the thin film transistor layer 130.

The first buffer layer 111 may be disposed on the substrate 110. The first buffer layer 111 may include an inorganic layer capable of preventing permeation of air or moisture. For example, the first buffer layer 111 may include a plurality of inorganic layers that are alternately stacked. In some cases, the buffer structure may in the first buffer layer 11 may increase the reliability of the display device 10 by protecting circuit elements from environmental degradation.

The lower metal layer BML may be disposed on the first buffer layer 111. The lower metal layer BML may block light from penetrating the semiconductor layer ACT of the thin film transistor TFT. For example, the lower metal layer BML may be formed as a single layer or multi-layer made of at least one of molybdenum (Mo), aluminum (Al), chromium (Cr), gold (Au), titanium (Ti), nickel (Ni), neodymium (Nd) and copper (Cu), or an alloy thereof. In some cases, the lower metal layer BML may reduce photo-induced leakage currents in the active semiconductor region.

The second buffer layer 113 may cover the first buffer layer 111 and the lower metal layer BML. The second buffer layer 113 may include an inorganic layer capable of preventing permeation of air or moisture. For example, the second buffer layer 113 may include a plurality of inorganic layers that are alternately stacked.

The thin film transistor TFT may be disposed on the second buffer layer 113. In one aspect, the thin film transistor TFT may be a component of a pixel circuit of the plurality of subpixels. For example, the thin film transistor TFT may be a driving transistor or a switching transistor of the pixel circuit. The thin film transistor TFT may include a semiconductor layer ACT, a source electrode SE, a drain electrode DE, and a gate electrode GE. The thin film transistor TFT may include a low-temperature polysilicon thin film transistor LTPS and/or an oxide thin film transistor. In some cases, the configuration of the thin film transistor TFT may be selectively optimized based on the emission characteristics of each subpixel type, such as quantum dot-based or inorganic LED-based structures.

The semiconductor layer ACT may be disposed on the second buffer layer 113. The semiconductor layer ACT may overlap the lower metal layer BML and the gate electrode GE in the thickness direction (e.g., the third direction DR3), and may be insulated from the gate electrode GE by the gate insulating layer 131. A material of the semiconductor layer ACT may be conductorized so that a portion of the semiconductor layer ACT may form the source electrode SE and the drain electrode DE. For example, the source electrode SE may be disposed at one side (or one end) of the semiconductor layer ACT and the drain electrode DE may be disposed at the other side (or the other end) of the semiconductor layer ACT. The gate electrode GE may be disposed on the gate insulating layer 131. The gate electrode GE may overlap the semiconductor layer ACT in the thickness direction, and the gate insulating layer 131 may be interposed the gate electrode GE and the semiconductor layer ACT. In some cases, the total width of the source electrode SE, the semiconductor layer ACT, and the drain electrode DE may be less than the width of the lower metal layer BML. However, embodiments are not necessarily limited thereto. In some cases, the overlap of the gate electrode GE with the active semiconductor region provides controlled charge modulation.

The gate insulating layer 131 may be disposed on the semiconductor layer ACT. For example, the gate insulating layer 131 may cover the semiconductor layer ACT and the second buffer layer 113. In some cases, the gate insulating layer 131 may cover the semiconductor layer ACT, the source electrode SE, the drain electrode DE, and the second buffer layer 113. The gate insulating layer 131 may be disposed between the semiconductor layer ACT and the gate electrode GE to insulate the semiconductor layer ACT from the gate electrode GE. The gate insulating layer 131 may include a contact hole through which the first connection electrode CNE1 passes. In one aspect, the contact hole facilitates electrical routing from the active device region to upper interconnect layers while maintaining insulation integrity.

The first interlayer insulating layer 133 may cover the gate electrode GE and the gate insulating layer 131. The first interlayer insulating layer 133 may include a contact hole through which the first connection electrode CNE1 passes. The contact hole of the first interlayer insulating layer 133 may be connected to the contact hole of the gate insulating layer 131 to a contact hole of the second interlayer insulating layer 135. For example, the contact holes may be vertically aligned. The vertical alignment of contact holes enables electrical continuity across multiple dielectric layers while maintaining structural isolation. In some cases, the first interlayer insulating layer 133 may also serve as a planarization layer, ensuring the that upper surface of the first interlayer insulating layer 133 I uniform. However, embodiments are not necessarily limited thereto.

The capacitor electrode CPE may be disposed on the first interlayer insulating layer 133. The capacitor electrode CPE may overlap the gate electrode GE in the thickness direction (e.g., the third direction DR3). The capacitor electrode CPE and the gate electrode GE may form capacitance (e.g., a storage capacitance). For example, the storage capacitance may be used to store a data voltage at the subpixel during a frame period, thereby stabilizing luminance output.

The second interlayer insulating layer 135 may cover the capacitor electrode CPE and the first interlayer insulating layer 133. The second interlayer insulating layer 135 may include a contact hole through which the first connection electrode CNE1 passes. The contact hole of the second interlayer insulating layer 135 may be connected to the contact hole of the first interlayer insulating layer 133 and the contact hole of the gate insulating layer 131.

The first connection electrode CNE1 may be disposed on the second interlayer insulating layer 135. The first connection electrode CNE1 may electrically connect the drain electrode DE of the thin film transistor TFT to the second connection electrode CNE2. The first connection electrode CNE1 may be in contact (e.g., direct contact and electrical contact) with the drain electrode DE of the thin film transistor TFT through the contact holes formed in the second interlayer insulating layer 135, the first interlayer insulating layer 133 and the gate insulating layer 131.

The first passivation layer 137 may cover the first connection electrode CNE1 and the second interlayer insulating layer 135. The first passivation layer 137 may protect the thin film transistor TFT. The first passivation layer 137 may include a contact hole through which the second connection electrode CNE2 passes. In some cases, the passivation layer 137 may protect the transistor structure from moisture, contaminants, and mechanical stress.

The second connection electrode CNE2 may be disposed on the first passivation layer 137. The second connection electrode CNE2 may electrically connect the first connection electrode CNE1 to pixel electrodes AE1 and AE2 of light emitting elements ED1 and ED2, respectively. The second connection electrode CNE2 may be electrically connected to a first alignment electrode AEL1 (and/or a second alignment electrode AEL2) of the third light emission area EA3. The second connection electrode CNE2 may be in contact with the first connection electrode CNE1 through the contact hole formed in the first passivation layer 137.

The second passivation layer 139 may cover the second connection electrode CNE2 and the first passivation layer 137. The second passivation layer 139 may include a contact hole through which the pixel electrodes AE1 and AE2 of the light emitting elements ED1 and ED2 and the first alignment electrode AEL1 of the third light emission area EA3 pass. In some embodiments, the second passivation layer 139 may include a contact hole through which the second alignment electrode AEL2 of the third light emission area EA3 passes. In some cases, the passivation layer 139 may be selectively patterned to expose electrode regions for electrical contact while maintaining protection over inactive areas.

The light emitting element layer 150 may be disposed on the first thin film transistor layer 130. The light emitting element layer 150 includes a bank layer 151 defining the plurality of light emission areas EA1, EA2. In one aspect, a plurality of light emitting elements ED1, ED2, and ED3 may be arranged in the plurality of light emission areas EA1, EA2 and EA3. The configuration of the light emitting element layer 150 enables hybrid emission functionality, integrating both quantum dot-based and inorganic LED-based subpixels within a shared pixel architecture.

The bank layer 151 may form the plurality of light emission areas EA1, EA2 and EA3 through the first, second, and third openings OP1, OP2 and OP3.

The plurality of light emitting elements ED1, ED2 and ED3 may include a first light emitting element ED1 disposed in the first light emission area EA1, a second light emitting element ED2 disposed in the second light emission area EA2, and a third light emitting element ED3 disposed in the third light emission area EA3. Each of the light emitting elements ED1, ED2 and ED3 may emit light having different colors, such as red, blue, green, and white. For example, the first light emitting element ED1 disposed in the first light emission area EA1 may emit light having a first color, which is red. The second light emitting element ED2 disposed in the second light emission area EA2 may emit light having a second color, which is green. The third light emitting element ED3 disposed in the third light emission area EA3 may emit light having a third color, which is blue. The three light emission areas EA1, EA2 and EA3 may form as one pixel. The three light emission areas EA1, EA2 and EA3 may include three light emitting elements ED1, ED2 and ED3, respectively, which emit light having different colors to represent a white gray scale. In an embodiment, the red and green subpixels may use quantum dot-based light emitting structures, and the blue subpixel includes an inorganic light emitting diode, thereby enhancing color performance and extended operational life of the blue light emitting element.

The first light emitting element ED1 disposed in the first light emission area EA1 may include a first pixel electrode AE1, a first light emitting structure EL1, and a common electrode CE. The second light emitting element ED2 disposed in the second light emission area EA2 may include a second pixel electrode AE2, a second light emitting structure EL2, and a common electrode CE. Hereinafter, the first light emitting element ED1 in the first light emission area EA1 and the second light emitting element ED2 in the second light emission area EA2 may be described first, and the third light emission area EA3 may be described later.

The first pixel electrode AE1 and the second pixel electrode AE2 are formed on the second passivation layer 139. The first pixel electrode AE1 and the second pixel electrode AE2 may be disposed in areas corresponding to the light emission areas EA1 and EA2, respectively. The first pixel electrode AE1 and the second pixel electrode AE2 may be electrically connected to the drain electrode DE of the thin film transistor TFT through the first connection electrode CNE1 and the second connection electrode CNE2. For example, the first pixel electrode AE1 may be electrically connected to second connection electrode CNE2, the first connection electrode CNE1, and the drain electrode DE of the thin film transistor TFT. For example, the second pixel electrode AE2 may be electrically connected to second connection electrode CNE2, the first connection electrode CNE1, and the drain electrode DE of the thin film transistor TFT. The first pixel electrode AE1 and the second pixel electrode AE2 may be spaced apart from each other on the second passivation layer 139. This separation ensures electrical isolation between adjacent color subpixels while enabling independent drive control of red and green emission units.

Each of the first pixel electrode AE1 and the second electrode AE2 may include a material that is transparent and has a high work function. The material may include indium-tin-oxide (ITO), indium-zinc-oxide (IZO), zinc oxide (ZnO), and indium oxide (In₂O₃). When each of the first pixel electrode AE1 and the second pixel electrode AE2 is a reflective electrode, each of the first pixel electrode AE1 and the second pixel electrode AE2 may have a stacked layer structure. For example, one layer of the stacked layer structure may include a material having the above-described high work function and the other layer may include reflective material such as silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or a combination thereof. For example, each of the first pixel electrode AE1 and the second electrode AE2 may have a multi-layered structure of ITO/Mg, ITO/MgF, ITO/Ag, and ITO/Ag/ITO, but the embodiment is not necessarily limited thereto.

The display device 10 may include a bank layer 151 disposed on the second passivation layer 139, the first pixel electrode AE1, and the second pixel electrode AE2. The bank layer 151 forms a plurality of openings OP1, OP2 and OP3 forming the light emission areas EA1, EA2 and EA3. The bank layer 151 is formed such that each of the pixel electrodes AE1 and AE2 is exposed by each of the openings OP1 and OP2. In some cases, a portion of the bank layer 151 may overlap end portions of the first pixel electrode AE1 and the second pixel electrode AE2. However, embodiments are not necessarily limited thereto. For example, the bank layer 151 may be disposed on the second passivation layer 139, and adjacent to the first pixel electrode AE1 and the second pixel electrode AE2.

The bank layer 151 may include an organic material. For example, the organic material may include an acrylic resin (polyacrylates resin), an epoxy resin, a phenolic resin, a polyamide resin, a polyimide resin, an unsaturated polyester resin, a polyphenylene ether resin, a polyphenylene sulfide resin, or benzocyclobutene (BCB).

The light emitting structures EL1 and EL2 of the first light emitting element ED1 and the second light emitting element ED2 may be respectively arranged on the pixel electrodes AE1 and AE2. In each of the light emitting structures EL1 and EL2, the thin film transistor TFT applies a voltage to the pixel electrodes AE1 and AE2 of the light emitting elements ED1 and ED2, and the common electrode CE of the light emitting elements ED1 and ED2 receives a common voltage or a cathode voltage, so that light may be emitted from the light emitting structures EL1 and EL2 of the light emitting elements ED1 and ED2.

The light emitting structures EL1 and EL2 may include a first light emitting structure EL1 and a second light emitting structure EL2, which are arranged in different light emission areas EA1 and EA2. The first light emitting structure EL1 may be disposed on the first pixel electrode AE1 in the first light emission area EA1, and the second light emitting structure EL2 may be disposed on the second pixel electrode AE2 in the second light emission area EA2. The light emitting structures EL1 and EL2 included in the display device 10 may include a quantum dot. For example, the quantum dot light emitting structures may be configured to emit red and green light based on the emission wavelength characteristics of the quantum dots.

An example of the first light emission area EA1 is shown in FIG. 6. The light emitting structures EL1 and EL2 are described with reference to the first light emitting structure EL1. In some cases, the structural and functional aspects described for the first light emitting structure EL1 may also apply to the second light emitting structure EL2 with corresponding adaptation for the second light emission area EA2.

The first light emitting structure EL1 may include a hole injection layer 153, a hole transport layer 154, a quantum dot light emitting layer 155, and an electron transport layer 157. Each of these layers may be sequentially stacked on the first pixel electrode AE1 to form a multilayer emission stack configured to optimize charge balance and luminous efficiency in the red-emitting quantum dot subpixel (or blue-emitting quantum dot subpixel in the second light emitting structure EL2).

The hole injection layer 153 may be disposed on the pixel electrode AE1. The hole injection layer 153 may serve to facilitate hole injection from the pixel electrodes AE1 and AE2 to the quantum dot light emitting layer 155.

For example, the hole injection layer 153 may include a phthalocyanine compound such as copper phthalocyanine, DNTPD(N,N′-diphenyl-N,N′-bis-[4-(phenyl-m-tolyl-amino)-phenyl]-biphenyl-4,4′-diamine), m-MTDATA(4,4′,4″-[tris(3-methylphenyl) phenylamino] triphenylamine), TDATA(4,4′4″-Tris(N,Ndiphenylamino)triphenylamine), 2-TNATA(4,4′,4″-tris{N,-(2-naphthyl)-N-phenylamino}-triphenylamine), PEDOT/PSS(Poly (3,4-ethylenedioxythiophene)/Poly(4-styrenesulfonate)), PANI/DBSA(Polyaniline/Dodecylbenzenesulfonic acid), PANI/CSA(Polyaniline/Camphor sulfonicacid), PANI/PSS(Polyaniline/Poly(4-styrenesulfonate)), NPD(N,N′-di(naphthalene-l-yl)-N,N′-diphenylbenzidine), polyether ketone (TPAPEK) containing triphenylamine, 4-Isopropyl-4′-methyldiphenyliodonium[Tetrakis(pentafluorophenyl)borate], and/or HAT-CN(dipyrazino [2,3-f: 2′,3′-h] quinoxaline-2,3,6,7,10,11-hexacarbonitrile).

The hole transport layer 154 may be disposed on the hole injection layer 153. The hole transport layer 154 may facilitate transportation of holes from the pixel electrodes AE1 and AE2 to the quantum dot light emitting layer 155. In some cases, for example, the hole transport layer 154 may include a carbazole-based derivative such as N-phenylcarbazole and polyvinyl carbazole, a fluorene-based derivative, TPD(N,N′-bis(3-methylphenyl)-N,N′-diphenyl-[1,1-biphenyl]-4,4′-diamine), a triphenylamine-based derivative such as TCTA(4,4′,4″-tris(N-carbazolyl)triphenylamine), NPD(N,N′-di(naphthalene-l-yl)-N,N′-diphenyl-benzidine), TAPC(4,4′-Cyclohexylidene bis[N,Nbis(4-methylphenyl)benzenamine]), HMTPD(4,4′-Bis[N,N′-(3-tolyl)amino]-3,3′-dimethylbiphenyl), and/or mCP(1,3-Bis(N-carbazolyl)benzene).

The quantum dot light emitting layer 155 may be disposed on the hole transport layer 154. The quantum dot light emitting layer 155 may include a plurality of quantum dots. Each quantum dot may be configured to emit light having a specific wavelength, such as red or green, based on the size and material composition of the quantum dot core and shell.

The quantum dots may adjust light emitting colors based on a particle size. The quantum dots may have various light emitting colors such as blue, red, and green by varying the particle sizes. As the particle size of the quantum dots becomes smaller, light having a short wavelength may be emitted. For example, when the quantum dots having the same core, a particle size of the quantum dot for emitting green light may be smaller than a particle size of the quantum dot for emitting red light. For example, when the quantum dots having the same core, a particle size of the quantum dot for emitting blue light may be smaller than the particle size of the quantum dot for emitting green light, but the embodiment is not necessarily limited thereto. The particle size may be adjusted based on a shell forming material, a shell thickness, and other properties even when the quantum dots have the same core. When the quantum dots have various light emitting colors such as blue, red and green, the quantum dots may have different core materials.

The particles of the quantum dots may be formed to have a shape such as a sphere, a pyramid, and/or a multi-arm. The particles of the quantum dots may be formed to have a shape such as a cubic nanoparticle, nanotube, nanowire, nanofiber, and/or nanoplate particle. In some cases, the shape of the quantum dot particles may influence the optical properties, packing density, and interaction with surrounding layers.

In some embodiments, the quantum dot light emitting layer 155 may include a core layer including quantum dot particles and a shell layer surrounding the core layer. The quantum dot particles may be liganded to inorganic particles on the surface or in the periphery of the shell layer. To prevent a phenomenon in which the quantum dot particles are ligand-bonded to the inorganic particles, a hydrothermal treatment process may be performed. Unlike a high-temperature annealing process of 150° C. or more, the hydrothermal treatment process of the quantum dot light emitting layer 155 may be performed by a low-temperature annealing process of 100° C. or less using steam. During the hydrothermal treatment process, the phenomenon in which quantum dot particles in the quantum dot light emitting layer 155 are ligand-bonded to the inorganic particles may be prevented.

In an embodiment, the quantum dot light emitting layer 155 including quantum dot particles is formed and then the hydrothermal treatment process is performed. In some cases, the present disclosure is not necessarily limited thereto. In some cases, other post-deposition treatments, such as UV curing, solvent annealing, or plasma processing, may be performed on the quantum dot light emitting layer 155.

In an embodiment, the hydrothermal treatment process may be performed when at least one layer, which includes nanoparticles, of the hole injection layer 153, the hole transport layer 154, or the electron transport layer 157 in addition to the quantum dot light emitting layer 155 is formed. For example, when at least one of the hole injection layer 153, the hole transport layer 154, the quantum dot light emitting layer 155, or the electron transport layer 157 is formed, the hydrothermal treatment process may be performed at least once at 100° C. or less using steam. In some cases, multiple hydrothermal treatment processes may be performed.

The quantum dots of the quantum dot light emitting layer 155 may include a group III-VI semiconductor compound, a group II-VI semiconductor compound, a group III-V semiconductor compound, a group III-VI semiconductor compound, a group I-III-VI semiconductor compound, a group IV-VI semiconductor compound, a group IV element or compound, or any combination thereof.

Examples of the group II-VI semiconductor compounds include diatomic compounds such as CdS, CdSe, CdTe, ZnS, ZnSe, ZnTe, ZnO, HgS, HgSe, HgTe, MgSe, and MgS. Examples of the group II-VI semiconductor compounds include ternary compounds such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, and MgZnS. Examples of the group II-VI semiconductor compounds include four-element compounds such as CdZnSeS, CdZnSeTe, CdZnSTe, CdHgSeS, CdHgSeTe, CdHgSTe, HgZnSeS, HgZnSeTe, and HgZnSTe. Examples of the group II-VI semiconductor compounds include a combination of diatomic compounds, ternary compounds, and four-element compounds.

Examples of the group III-V semiconductor compounds include diatomic compounds such as GaN, GaP, GaAs, GaSb, AlN, AlP, AlAs, AlSb, InN, InP, InAs, and InSb. Examples of the group III-V semiconductor compounds include ternary compounds such as GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, and GaAlNP. Examples of the group III-V semiconductor compounds include four-element compounds such as GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb. Examples of the group III-V semiconductor compounds include a combination of diatomic compounds, ternary compounds, and four-element compounds. The group III-V semiconductor compound may further include a group II element. Examples of the Group III-V semiconductor compound further including a group II element may include InZnP, InGaZnP, InAlZnP, and other compounds.

Examples of the group III-VI semiconductor compounds may include diatomic compounds such as GaS, Ga₂S₃, GaSe, Ga₂Se₃, GaTe, InS, InSe, In₂Se₃, and InTe, ternary compounds such as InGaS₃, and InGaSe₃, or any combination thereof.

Examples of the group I-III-VI semiconductor compounds may include ternary compounds such as AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, and AgAlO₂, four-element compounds such as AgInGaS₂, and AgInGaSe₂, or any combination thereof.

Examples of the group IV-VI group semiconductor compounds may include diatomic compounds such as SnS, SnSe, SnTe, PbS, PbSe, and PbTe. Examples of the group IV-VI group semiconductor compounds may include ternary compounds such as SnSeS, SnSeTe, SnSTe, PbSeS, PbSeTe, PbSTe, SnPbS, SnPbSe, and SnPbTe. Examples of the group IV-VI group semiconductor compounds may include four-element compounds such as SnPbSSe, SnPbSeTe, and SnPbSTe. Examples of the group IV-VI semiconductor compounds include a combination of diatomic compounds, ternary compounds, and four-element compounds.

The group IV element or compound may include a single element such as Si and Ge, a diatomic compound such as SiC and SiGe, or any combination thereof.

Each element included in the multi-element compound, such as the diatomic compound, the ternary compound, and the four-element compound, may exist in the particles at a uniform or non-uniform concentration. For example, the above chemical elements and compounds refer to the kinds of elements included in the compounds, and an element ratio in the compounds may be different. For example, AgInGaS₂ may represent AgInₓGa₁₋ₓS₂ (where x is a real number between 0 and 1).

The quantum dots may have a single structure or a double structure of a core-shell, in which the concentration of each element included in the corresponding quantum dots is uniform. For example, a material included in the core and a material included in the shell may be different from each other.

The shell of the quantum dots may serve as a passivation layer for maintaining semiconductor properties by preventing chemical denaturation of the core and/or a charging layer for imparting electrophoretic properties to the quantum dots. The shell may be a single layer or a multi-layered structure. An interface between the core and the shell may have a concentration gradient in which the concentration of the element present in the shell is lowered toward the center. In some cases, for example, the gradient shell structure may reduce lattice mismatch and interfacial stress between the core and shell, thereby enhancing structural stability and optical performance of the quantum dots.

Examples of the shell of the quantum dots may include an oxide of metal or non-metal, a semiconductor compound, or a combination thereof. Examples of the oxide of metal or non-metal may include diatomic compounds such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO. Examples of the oxide of metal or non-metal may include ternary compounds such as MgAl₂O₄, CoFe₂O₄, NiFe₂O₄, and CoMn₂O₄. Examples of the oxide of metal or non-metal may include a combination of the diatomic compound and the ternary compounds. Examples of the semiconductor compound may include the group III-VI semiconductor compound, the group II-VI semiconductor compound, the group III-VI semiconductor compound, the group III-VI semiconductor compound, the group I-III-VI semiconductor compound, the group IV-VI semiconductor compound, or any combination thereof. For example, the semiconductor compound may include CdS, CdSe, CdTe, ZnS, ZnSe, ZnTe, ZnSeS, ZnTeS, GaAs, GaP, GaS, GaSe, AgGaS, AgGaS₂, GaSb, HgS, HgSe, HgTe, InAs, InP, InGaP, InSb, AlAs, AlP, AlSb, or any combination thereof.

Each element included in the multi-element compound, such as the diatomic compound and the ternary compound, may exist in the particles at a uniform or non-uniform concentration. For example, the above chemical compounds refer to the kinds of elements included in the compounds, and an element ratio in the compound may be different.

The quantum dot may have a full width of half maximum (FWHM) of an emission wavelength spectrum of about 45 nm or less, about 40 nm or less, or about 30 nm or less. Within this range, color purity or color reproducibility may be improved. In some cases, since the light emitted through the quantum dot is emitted in all directions, a light viewing angle may be improved. In some cases, narrow FWHM enables more saturated colors and precise coverage, while isotropic emission enhances luminance uniformity across wide viewing angles in the display device.

The quantum dot may have a shape such as a sphere, a pyramid, a multi-arm, a cubic nanoparticle, nanotube, nanowire, nanofiber, and nanoplate particle.

Since an energy band gap may be adjusted by adjusting a size of the quantum dot or the element ratio in the quantum dot compound, light of various wavelength bands may be generated from the quantum dot light emitting layer 155. Therefore, the light emitting element may be implemented by using the above-described quantum dots (e.g., the quantum dots having different sizes or the quantum dots having different element ratios in the quantum dot compound). For example, the size of the quantum dot or the element ratio in the quantum dot compound may be adjusted to emit red light, green light, and/or blue light. In addition, the quantum dots may be configured to emit white light by combining different light having various colors.

The electron transport layer 157 may be disposed on the quantum dot light emitting layer 155. The electron transport layer 157 may facilitate injection and transport of electrons from the common electrode CE to the quantum dot light emitting layer 155. The electron transport layer 157 may include a composition for an electron transport layer, and the composition for an electron transport layer may include inorganic particles. The inorganic particles may include a metal oxide. For example, the electron transport layer 157 of the display device 10 may include ZnMgO or ZnO, but is not necessarily limited thereto. In addition, the electron transport layer 157 may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, SnO₂, Ta₂O₃, ZrO₂, HfO₂, and Y₂O₃. In some cases, the electron transport layer 157 may include a ternary compound such as ZnMgO, MgAl₂O₄, CoFe₂O₄, NiFe₂O₄, CoMn₂O₄, BaTiO₃, BaZrO₃, and ZrSiO₄.

In some embodiments, the hole injection layer 153, the hole transport layer 154, the quantum dot light emitting layer 155, and the electron transport layer 157, which makes up each of the light emitting structures EL1 and EL2, may be manufactured by an inkjet printing process. For example, the inkjet printing process is a material deposition technique that ejects tiny droplets of functional ink onto a substrate through nozzles, using either thermal or piezoelectric actuation.

The common electrode CE may be disposed on each of the light emitting structures EL1 and EL2. The common electrode CE may cover both the light emitting structures EL1 and EL2, which are disposed in each of the light emission areas EA1 and EA2, and the bank layer 151. For example, the common electrode CE may be uniformly formed on both the first light emitting structure EL1 and the second light emitting structure EL2. However, the common electrode CE might not overlap the third light emission area EA3 and thus might not be disposed in the third light emission area EA3. For example, the common electrode CE may be arranged to continuously extend in the first light emission area EA1 and the second light emission area EA2, and might not be disposed in the third light emission area EA3. This configuration allows independent optimization of the third light emission area EA3, which may include a different drive structure or light emitting mechanism, such as an inorganic light emitting diode, different from the quantum dot-based structures in the first light emission area EA1 and the second light emission area EA2.

The common electrode CE includes a transparent conductive material so that light generated by the light emitting structures EL1 and EL2 may be emitted. The common electrode CE may receive a common voltage or a low potential voltage. When the pixel electrodes AE1 and AE2 receive a voltage corresponding to a data voltage and the common electrode CE receives a low potential voltage, a potential difference is formed between the pixel electrodes AE1 and AE2 and the common electrode CE. Thus, the light emitting structures EL1 and EL2 may emit light. The transparent material of the common electrode CE enables upward emission of generated light through an upper surface of the display device.

The common electrode CE may include a material (e.g., element or compound) having a low work function, such as lithium (Li), calcium (Ca), lithium fluoride/calcium (LiF/Ca), lithium fluoride/aluminum (LiF/Al), aluminum (Al), magnesium (Mg), silver (Ag), platinum (Pt), palladium (Pd), nickel (Ni), gold (Au), neodymium (Nd), iridium (Ir), chromium (Cr), barium fluoride (BaF), barium (Ba), or a compound (e.g., a mixture of Ag and Mg) thereof. The common electrode CE may further include a transparent metal oxide layer disposed on the material layer having a low work function. In some cases, for example, the transparent metal oxide layer, such as indium tin oxide (ITO) or zinc oxide (ZnO), may enhance optical transmittance, protect the underlying low-work-function material from oxidation, and improve electrode stability under prolonged operation.

In some embodiments, the common electrode CE may include a capping layer on the transparent conductive metal layer. The capping layer may serve to protect the transparent conductive metal. For example, the common electrode CE may be a single layer including a conductive metal or a multi-layer including a conductive metal and a capping layer.

Referring back to FIG. 5, the light emitting element layer 150 of the third light emission area EA3 includes the third light emitting element ED3, an alignment electrode AEL, a first insulating layer INS1, a second insulating layer INS2, and a contact electrode CTE. The structural configuration of the third light emitting element ED3 may be different from the structural configuration of the first and second light emitting elements ED1 and ED2 to accommodate a different emission mechanism or material system, such as inorganic light emitting diodes.

In some cases, the third light emission area EA3 may uses a light modulation or light extraction structure different from the quantum dot-based structures of the first and second light emission areas EA1 and EA2. This allows the display device 10, so that the lifespans of red light, green light, and blue light may be adjusted to an equivalent level.

Referring to FIGS. 5, 7 and 8, the alignment electrode AEL may be disposed on the second passivation layer 139. The alignment electrode AEL may be disposed in an area corresponding to the third light emission area EA3. The alignment electrode AEL may be disposed in the third light emission area EA3 and protruding away from and upper layer of the second passivation layer 139. The alignment electrode AEL may extend in the second direction DR2, and thus may be arranged in the third light emission area EA3 and the sub-area SA. The alignment electrodes AEL may be spaced apart from each other in the first direction DR1. The sub-area SA may be an area disposed above and below the third light emission area EA3. The alignment electrode AEL may be electrically connected to the third light emitting element ED3.

The alignment electrode AEL may include a first alignment electrode AEL1 and a second alignment electrode AEL2. The first alignment electrode AEL1 may be disposed at a left side of the third light emission area EA3, and the second alignment electrode AEL2 may be spaced apart from the first alignment electrode AEL1 in the first direction DR1 and thus may be disposed at a right side of the third light emission area EA3. The first alignment electrode AEL1 and the second alignment electrode AEL2 may be partially arranged in the corresponding third light emission area EA3 and a non-light emission area BA adjacent thereto. The first alignment electrode AEL1 and the second alignment electrode AEL2 of different third light emission areas EA3 may be spaced apart from each other based on a separation portion ROP positioned in the sub-area SA. In some cases, the first alignment electrode AEL1 and the second alignment electrode AEL2 may be disposed at a same layer (e.g., on the second passivation layer) as the first pixel electrode AE1 of the first light emission area EA1 and the second pixel electrode AE2 of the second light emission area EA2, and may include the same material.

The first alignment electrode AEL1 and the second alignment electrode AEL2 may be in direct contact with the second connection electrode CNE2 and the voltage line VL through electrode contact holes CTD and CTS between the sub-areas SA. For example, the first alignment electrode AEL1 may be in direct contact with the second connection electrode CNE2 through electrode contact hole CTD. The second alignment electrode AEL2 may be in direct contact with the voltage line VL through electrode contact hole CTS. The first alignment electrode AEL1 may be in contact with the second connection electrode CNE2 through the first electrode contact hole CTD passing through the second passivation layer 139. The second alignment electrode AEL2 may be in contact with the voltage line VL through the second electrode contact hole CTS passing through the second passivation layer 139. The first alignment electrode AEL1 may be electrically connected to the thin film transistor TFT through the second connection electrode CNE2 so that a first power voltage may be applied to the first alignment electrode AEL1, and the second alignment electrode AEL2 may be electrically connected to the voltage line VL so that a second power voltage may be applied to the second alignment electrode AEL2, but the present disclosure is not necessarily limited thereto. By applying different voltages to the first alignment electrode AEL1 and the second alignment electrode AEL2, an electric field gradient may be formed across the third light emission area EA3, enabling fine control over the first alignment electrode AEL1 and the second alignment electrode AEL2.

The alignment electrode AEL may be formed in the same manner as the pixel electrodes AE1 and AE2 described above. For example, the alignment electrode AEL may include a material that is transparent and exhibit a high work function, such as indium-tin-oxide (ITO), indium-zinc-oxide (IZO), zinc oxide (ZnO), and indium oxide (In₂O₃). When the alignment electrode AEL is a reflective electrode, the alignment electrode AEL may have a stacked layer structure including a material having the high work function and a reflective material such as silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or a combination thereof. For example, the alignment electrode AEL may have a multi-layered structure of ITO/Mg, ITO/MgF, ITO/Ag, and ITO/Ag/ITO, but is not necessarily limited thereto.

The first insulating layer INS1 may be disposed on the entire surface (e.g., an upper surface and side surfaces) of alignment electrode AEL in the third light emission area EA3 and the sub-area SA, and may be disposed on the second passivation layer 139 and the alignment electrode AEL. The first insulating layer INS1 might not overlap the first light emission area EA1 and the second light emission area EA2, and may overlap the third light emission area EA3. The first insulating layer INS1 may protect the alignment electrode AEL and simultaneously insulate the alignment electrode AEL from another alignment electrode AEL. In one aspect, since the first insulating layer INS1 covers the alignment electrode AEL before the bank layer 151 is formed, the alignment electrode AEL may be prevented from being damaged during the formation of the bank layer 151. Also, the first insulating layer INS1 may prevent the third light emitting element ED3 arranged thereon from being damaged by direct contact with other members.

In an embodiment, the first insulating layer INS1 may include a first area FP and a second area SP. The first area FP may be an area that overlaps a plurality of third light emitting elements ED3, and the second area SP may be an area other than the first area FP. The second area SP may be relatively thicker than the first area FP. In an embodiment, the first area FP may overlap the third light emission area EA3, and the second area SP may overlap the sub area SA. The first area FP may be configured to insulate the third light emitting element ED3 from the alignment electrodes AEL, and the second area SP may serve as a dam for distinguishing the third light emission area EA3 from the sub-area SA to partially prevent the ink from spreading between the adjacent third light emission areas EA3 during the inkjet process.

A portion of the bank layer 151 may be disposed on the first insulating layer INS1. For example, the bank layer 151 may overlap the first insulating layer INS1 in the second area SP. The bank layer 151 may prevent the ink overflow into the first light emission area EA1 and the second light emission area EA2, which are adjacent to the third light emission areas EA3, during the inkjet process. In an embodiment, a portion of the bank layer 15 surrounding the first light emission area EA1 and the second light emission area EA2 may be arranged in a grid shape. A portion of the bank layer 151 surrounding the third light emission area EA3 may be arranged in a line shape. For example, the bank layer 151 may be arranged so as not to individually partition the plurality of third light emission areas EA3 arranged in the second direction DR2 from each other.

The plurality of third light emitting elements ED3 may be disposed in the third light emission area EA3. The third light emitting elements ED3 may be spaced apart from each other in the second direction DR2. In an embodiment, the plurality of third light emitting elements ED3 may have a shape extending in one direction, and both ends of third light emitting elements ED3 may be arranged on different alignment electrodes AEL, respectively. For example, one side of the third light emitting element ED3 may be disposed on the first alignment electrode AEL1, and the other side of third light emitting elements ED3 may be disposed on the second alignment electrode AEL2. A length of the third light emitting element ED3 may be longer than a distance between the alignment electrodes AEL spaced apart from each other in the first direction DR1. The third light emitting elements ED3 may be disposed in the first direction DR1 crossing (or perpendicular to) the second direction DR2, in which the alignment electrode AEL extends.

The plurality of third light emitting elements ED3 may be disposed on the first insulating layer INS1. The third light emitting elements ED3 may have a shape extending in one direction parallel with an upper surface of the substrate 110. The third light emitting elements ED3 may be electrically connected to the contact electrodes CTE, and an electric signal may be applied to the contact electrodes CTE to emit light having a target wavelength band. In an embodiment, the target wavelength band may correspond to red, green, or blue light, based on the structural configuration of the third light emitting element ED3. For example, the electric signal may be applied to the contact electrodes CTE to emit light having a blue color. In some cases, the contact electrodes CTE include a first contact electrode CTE1 and a second contact electrode CTE2 spaced apart from the first contact electrode CTE1.

The second insulating layer INS2 may be disposed on the plurality of third light emitting elements ED3 and the first insulating layer INS1 in the third light emission area EA3. The second insulating layer INS2 might not overlap the first light emission area EA1 and the second light emission area EA2, and may overlap the third light emission area EA3. The second insulating layer INS2 may extend in the second direction DR2 to cover a portion of the plurality of third light emitting elements ED3. The second insulating layer INS2 may be formed as an island-shaped pattern, and may partially surround outer surfaces (e.g., an upper surface) of the third light emitting elements ED3, and might not cover respective side surfaces or respective ends of the third light emitting elements ED3. The second insulating layer INS2 may protect the third light emitting elements ED3 and simultaneously fix the third light emitting elements ED3 in the manufacturing process of the display device 10.

The plurality of contact electrodes CTE disposed on the plurality of alignment electrodes AEL, the first insulating layer INS1, and the second insulating layer INS2 may have a shape extending in one direction, and may be spaced apart from each other. Each of the contact electrodes CTE may be in contact with the third light emitting element ED3.

The plurality of contact electrodes CTE may include a first contact electrode CTE1 and a second contact electrode CTE2. The first contact electrode CTE1 may be disposed on the first alignment electrode AEL1, and may partially overlap the first alignment electrode AEL1. The first contact electrode CTE1 may extend from the third light emission area EA3 to the sub-area SA. The second contact electrode CTE2 may be disposed on the second alignment electrode AEL2 and may extend in the second direction DR2. The second contact electrode CTE2 may partially overlap the second alignment electrode AEL2, and may extend from the third light emission area EA3 to the sub-area SA. The first contact electrode CTE1 and the second contact electrode CTE2 are in contact with corresponding ends of the third light emitting elements ED3, respectively, and may be electrically connected to the alignment electrodes AEL or the conductive layer below the alignment electrodes AEL.

For example, the first contact electrode CTE1 and the second contact electrode CTE2 are disposed on sides of the second insulating layer INS2 and may be in contact with the third light emitting elements ED3. The first contact electrode CTE1 may partially overlap the first alignment electrode AEL1, and may be in contact with one end portion of the third light emitting elements ED3. The second contact electrode CTE2 may partially overlap the second alignment electrode AEL2, and may be in contact with the opposite end portion of the third light emitting elements ED3.

The plurality of contact electrodes CTE are disposed in the third light emission area EA3 and the sub-area SA. The contact electrodes CTE may be in contact with the third light emitting elements ED3 at a portion in the third light emission area EA3, and may be electrically connected to the second connection electrode CNE2 and the voltage line VL at a portion in the sub-area SA. In addition, the first contact electrode CTE1 and the second contact electrode CTE2 may include the same material as the material of the common electrode CE formed in the first light emission area EA1 and the second light emission area EA2.

According to an embodiment, the plurality of contact electrodes CTE may be in contact with the alignment electrode AEL through contact portions CT1 and CT2 in the sub-area SA. The first contact electrode CTE1 may be in contact with the first alignment electrode AEL1 through the first contact portion CT1 passing through the first insulating layer INS1 in the sub-area SA. The second contact electrode CTE2 may be in contact with the second alignment electrode AEL2 through the second contact portion CT2 passing through the first insulating layer INS1 in the sub-area SA. Each of the contact electrodes CTE may be electrically connected to the second connection electrode CNE2 and the voltage line VL through the alignment electrodes AEL. The first contact electrode CTE1 may be electrically connected to the thin film transistor TFT so that a first power voltage may be applied to the first contact electrode CTE1, and the second contact electrode CTE2 may be electrically connected to the voltage line VL so that a second power voltage may be applied to the second contact electrode CTE2. Each contact electrode CTE may be in contact with the third light emitting element ED3 in the third light emission area EA3 to transmit a power voltage to the third light emitting element ED3. Thus, this configuration allows independent voltage application to each contact electrode, enabling precise control of power delivery to the third light emitting elements ED3.

The contact electrodes CTE may include a conductive material. For example, the contact electrodes CTE may be formed in the same manner as the common electrode CE. For example, the contact electrode CTE may include a material layer having a low work function, such as lithium (Li), calcium (Ca), lithium fluoride/calcium (LiF/Ca), lithium fluoride/aluminum (LiF/Al), aluminum (Al), magnesium (Mg), silver (Ag), platinum (Pt), palladium (Pd), nickel (Ni), gold (Au), neodymium (Nd), iridium (Ir), chromium (Cr), barium fluoride (BaF), barium (Ba), or a compound (e.g., a mixture of Ag and Mg) thereof. The contact electrode CTE may further include a transparent metal oxide layer disposed on the material layer having a low work function. In some embodiments, the contact electrode CTE may include a capping layer disposed on the transparent conductive metal layer. The capping layer may be configured to protect the transparent conductive metal. For example, the contact electrode CTE may be a single layer including a conductive metal or a multi-layer including a conductive metal and a capping layer.

The display device 10 may include a hybrid pixel architecture using quantum dot-based first and second light emission areas (EA1 and EA2) with a third light emission area (EA3) including inorganic light emitting diode. This hybrid configuration improves color coverage, enhances luminance efficiency, and extends device lifetime. The quantum dot subpixels provide high color purity, and the inorganic third subpixel provides superior spectral stability and longevity.

The alignment electrodes AEL and contact electrodes CTE disposed in the third light emission area EA3 enable independent and precise electrical control of the third light emitting elements ED3. By applying separate voltages to first and second alignment electrodes AEL1 and AEL2, the display device can modulate polarization states. This improves optical performance, such as enhanced light extraction efficiency or angular emission control.

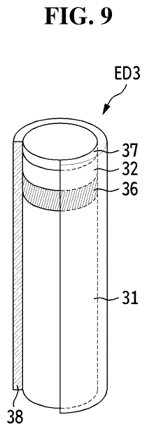

FIG. 9 is a schematic view illustrating a third light emitting element according to an embodiment. In an embodiment, the third light emitting element ED3 may be an inorganic light emitting diode.

Referring to FIG. 9, the third light emitting element ED3 may be a light emitting diode. For example, the light emitting element ED may be an inorganic light emitting diode made of an inorganic material, which has a size of nano-to micro-meter. When an electric field is formed in a specific direction between two electrodes facing each other, the third light emitting element ED3 may be aligned between the two electrodes in which a polarity is formed.

The third light emitting element ED3 may extend in one direction. The third light emitting element ED3 may have a shape such as a cylinder, a rod, a wire, or a tube, but the shape of the third light emitting element ED3 is not necessarily limited thereto. The third light emitting element ED3 may have various shapes such as a shape of a polygonal column, a cube, a rectangular parallelepiped, and a hexagonal column. In some cases, the third light emitting element ED3 may have a shape that extends in one direction and may also have a partially inclined outer surface.

The third light emitting element ED3 may include a semiconductor layer doped with any conductivity type (e.g., p-type or n-type) dopant. The semiconductor layer may emit light having a specific wavelength band based on an electrical signal applied from an external power source. The third light emitting element ED3 may include a first semiconductor layer 31, a second semiconductor layer 32, a light emitting layer 36, an electrode layer 37, and an insulating layer 38.

The first semiconductor layer 31 may be an n-type semiconductor. The first semiconductor layer 31 may include a semiconductor material having a chemical formula of AlₓGa_{y}In_{1-x-y}N (where 0≤x≤1, 0≤y≤1, 0≤x+y≤1). For example, the first semiconductor layer 31 may include at least one of AlGaInN, GaN, AlGaN, InGaN, AlN, or InN, which are doped with n-type dopants. The n-type dopants doped in the first semiconductor layer 31 may be silicon (Si), germanium (Ge), tin (Sn), selenium (Se), or other suitable elements.

The second semiconductor layer 32 is disposed on the first semiconductor layer 31 with the light emitting layer 36 interposed between the second semiconductor layer 32 and the first semiconductor layer 31. The second semiconductor layer 32 may be a p-type semiconductor, and may include a semiconductor material having a chemical formula of AlₓGa_{y}In_{1-x-y}N (where 0≤x≤1, 0≤y≤1, 0≤x+y≤1). For example, the second semiconductor layer 32 may include at least one of AlGaInN, GaN, AlGaN, InGaN, AlN, or InN, which are doped with p-type dopants. The p-type dopants doped in the second semiconductor layer 32 may be magnesium (Mg), zinc (Zn), calcium (Ca), barium (Ba), or other suitable elements.

The first semiconductor layer 31 and the second semiconductor layer 32 are shown as being formed as a single layer, but are not necessarily limited thereto. The first semiconductor layer 31 and the second semiconductor layer 32 may further include a larger number of layers, such as a clad layer or a tensile strain barrier reducing (TSBR) layer, based on the material of the light emitting layer 36. For example, the third light emitting element ED3 may further include another semiconductor layer disposed between the first semiconductor layer 31 and the light emitting layer 36 or between the second semiconductor layer 32 and the light emitting layer 36. The semiconductor layer disposed between the first semiconductor layer 31 and the light emitting layer 36 may include at least one of AlGaInN, GaN, AlGaN, InGaN, AlN, InN, or SLs, which are doped with n-type dopants. The semiconductor layer disposed between the second semiconductor layer 32 and the light emitting layer 36 may include at least one or of AlGaInN, GaN, AlGaN, InGaN, AlN, or InN, which are doped with p-type dopants.

The light emitting layer 36 is disposed between the first semiconductor layer 31 and the second semiconductor layer 32. The light emitting layer 36 may include a material having a single or multiple quantum well structure. When the light emitting layer 36 includes a material having a multiple quantum well structure, a plurality of quantum layers and a plurality of well layers may be alternately stacked. The light emitting layer 36 may emit light based on the combination of electron-hole pairs and electrical signals applied through the first semiconductor layer 31 and the second semiconductor layer 32. The light emitting layer 36 may include a material such as AlGaN, AlGaInN, and InGaN. For example, when the light emitting layer 36 has a stacked structure of quantum layers and well layers, which are alternately stacked in a multiple quantum well structure, the quantum layer may include a material such as AlGaN or AlGaInN, and the well layer may include a material such as GaN or AlInN.

The light emitting layer 36 may have a structure having varied band gap energy. For example, a first layer of the light emitting layer 36 may include a semiconductor material having a large band gap energy and a second layer of the light emitting layer 36 may include semiconductor materials having a small band gap energy. In some cases, the light emitting layer 36 may include group-III or group-V semiconductor materials based on a wavelength band of the emitted light. The light emitting layer 36 may emit light having a red or green wavelength band without limitation to light of a blue wavelength band. This flexibility in material composition and bandgap configuration enables optimization of light emitting diodes for various color channels within the display device 10.

The electrode layer 37 may be an ohmic connection electrode, but is not necessarily limited thereto. The electrode layer 37 may be a Schottky connection electrode. The third light emitting element ED3 may include at least one electrode layer 37. The third light emitting element ED3 may include one or more electrode layers 37, but is not necessarily limited thereto. In some cases, the light emitting element ED3 might not include an electrode layer 37.

The electrode layer 37 may reduce resistance between the third light emitting element ED3 and an electrode or a connection electrode when the third light emitting element ED3 is electrically connected with the electrode or the connection electrode in the display device 10. The electrode layer 37 may include a metal having conductivity. For example, the electrode layer 37 may include at least one of Al, Ti, In, Au, Ag, ITO, IZO, or ITZO.

The insulating layer 38 surrounds outer surfaces of the plurality of semiconductor layers and the electrode layer. For example, the insulating layer 38 may surround at least an outer surface of the light emitting layer 36, and may be formed to expose both ends in a longitudinal direction of the third light emitting element ED3. Also, the insulating layer 38 may be formed with a rounded upper surface on a section in an area adjacent to at least one end of the third light emitting element ED3. In some cases, for example, the insulating layer 38 may surround outer surfaces of the first semiconductor layer 31, the second semiconductor layer 32, the light emitting layer 36, and the electrode layer 37.

The insulating layer 38 may include materials having insulation property, for example, at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ). The insulating layer 38 is illustrated as being formed as a single layer, but is not necessarily limited thereto. In some embodiments, the insulating layer 38 may be formed as a multi-layered structure in which multiple layers are stacked.

The insulating layer 38 may serve to protect the semiconductor layers and the electrode layer of the light emitting element ED. The insulating layer 38 may prevent an electrical short from occurring, which may occur in the light emitting layer 36 when the third light emitting element ED3 is directly in contact with the electrode to which the electrical signal is transferred. In addition, the insulating layer 38 may prevent light emitting efficiency of the third light emitting element ED3 from being deteriorated. By electrically isolating sensitive regions and minimizing leakage currents, the insulating layer 38 enhances device reliability and preserves luminous efficiency over operational lifetime.

Also, an outer surface of the insulating layer 38 may be surface-treated. The third light emitting element ED3 may be aligned by spraying the third emitting element ED3 onto the electrode while dispersed in an ink. The surface of the insulating layer 38 may be hydrophobic-treated or hydrophilic-treated, so that the third light emitting element ED3 may be dispersed in the ink without condensed with another third light emitting element ED3 adjacent to the third light emitting element ED3.

According to the above-described embodiment, the first light emission area EA1 that emits red light and the second light emission area EA2 that emits green light may include light emitting structures EL1 and EL2 that include the quantum dot light emitting layer 155, and the third light emission area EA3 that emits blue light may include the third light emitting element ED3 having an inorganic light emitting diode. The quantum dot light emitting layer that emits blue light has a relatively shorter lifespan than the quantum dot light emitting layer that emits red light or green light. In the present embodiment, the third light emitting element ED3 of the light emitting diode may be used in the third light emission area EA that emits blue light, so that the lifespans of red light, green light and blue light may be adjusted to an equivalent level. Accordingly, the display quality of the display device 10 may be improved.

Hereinafter, a method for manufacturing the display device 10 are described with reference to other drawings. The manufacturing with reference to the cross-sectional view of the display device 10 shown in FIG. 5 is described as an example, and a manufacturing process subsequent to the first passivation layer 137 may be omitted. A known method may be applied to the manufacturing process subsequent to the first passivation layer 137.

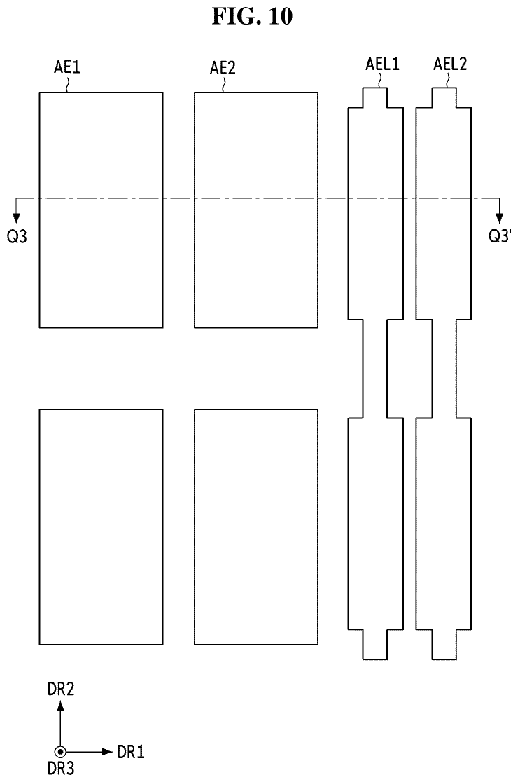

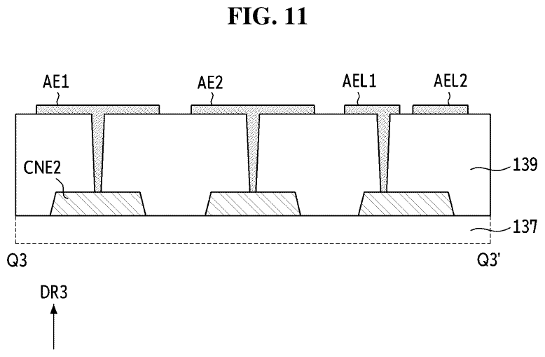

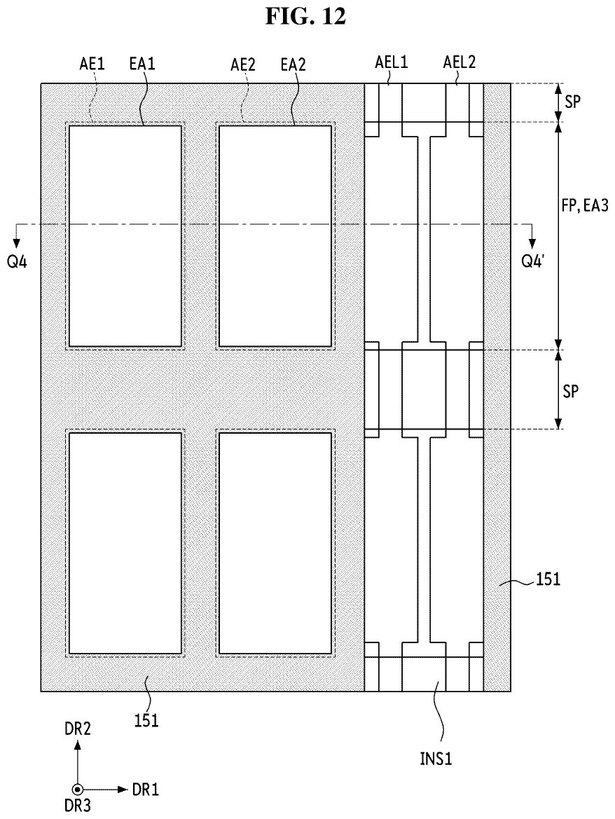

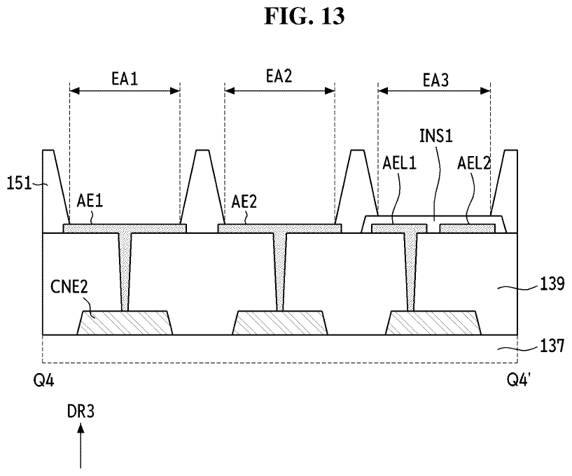

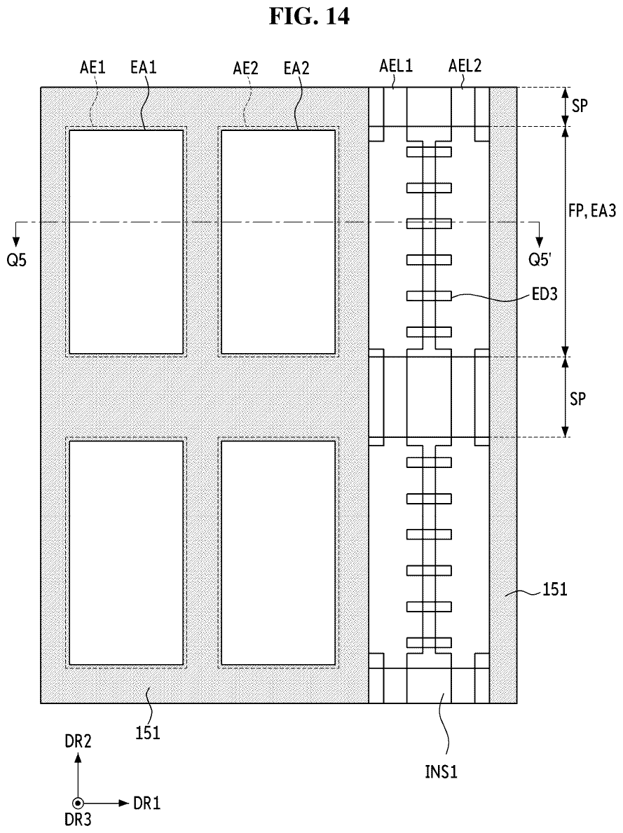

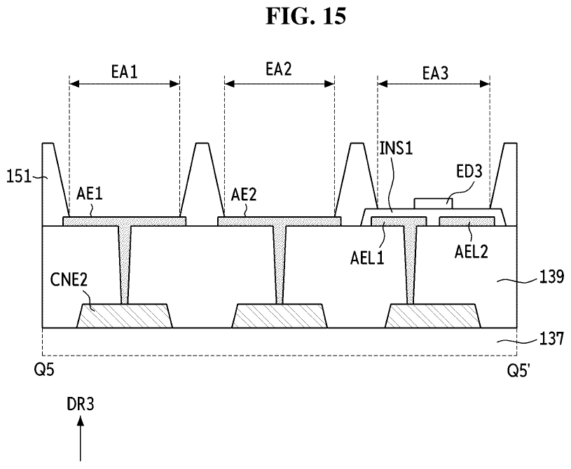

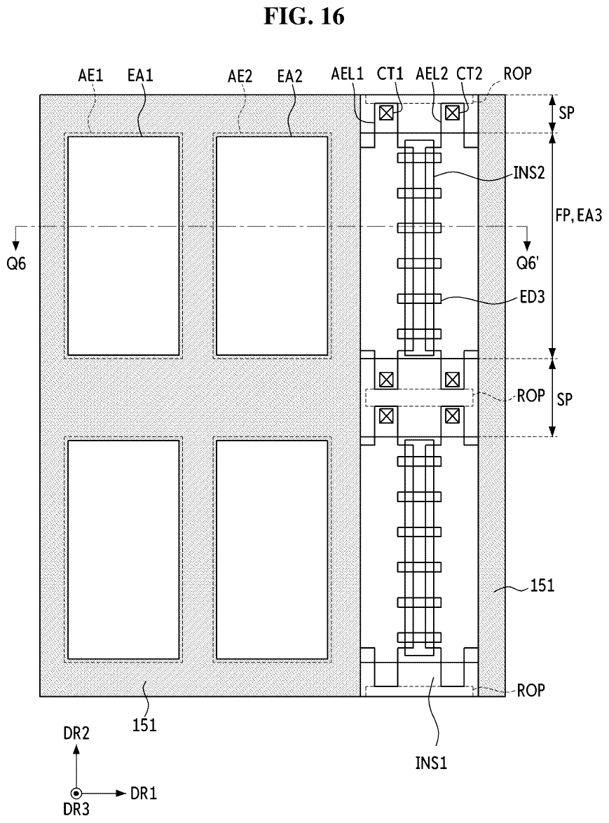

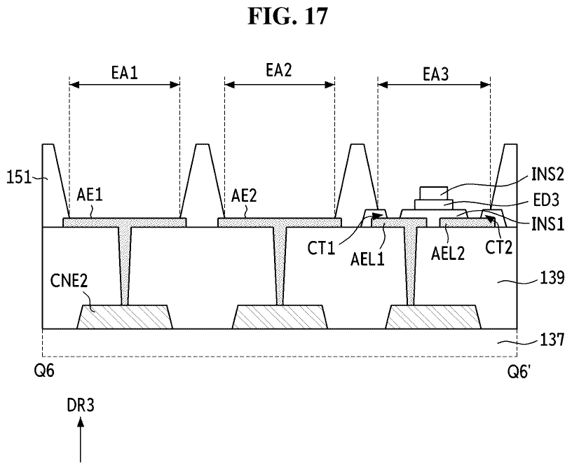

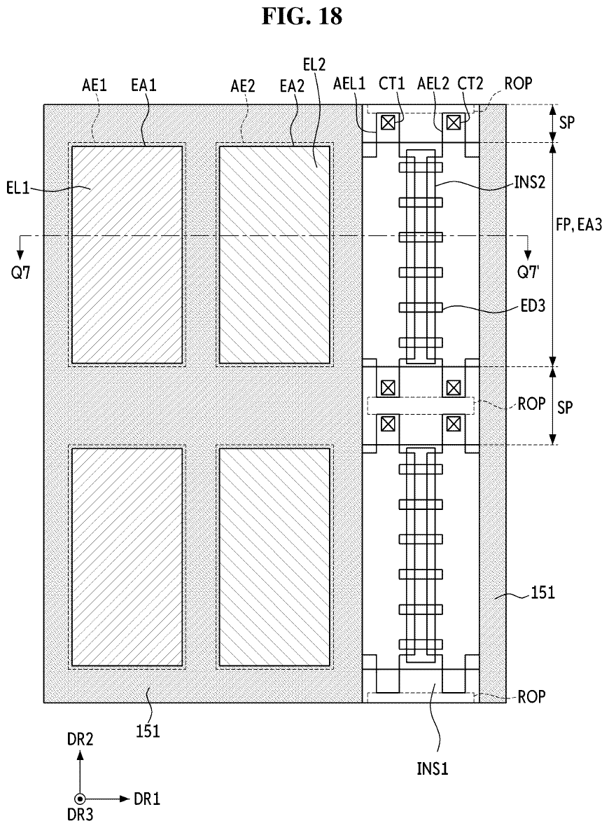

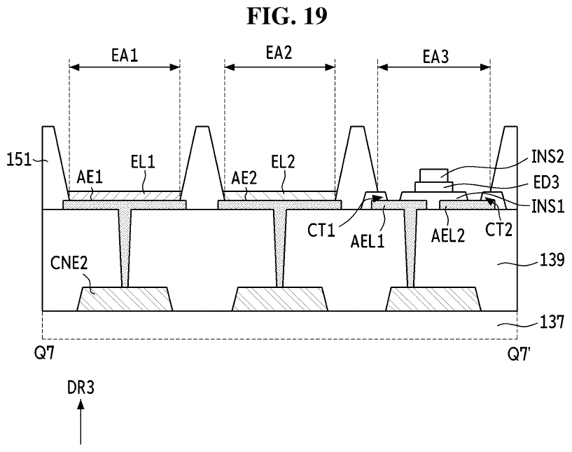

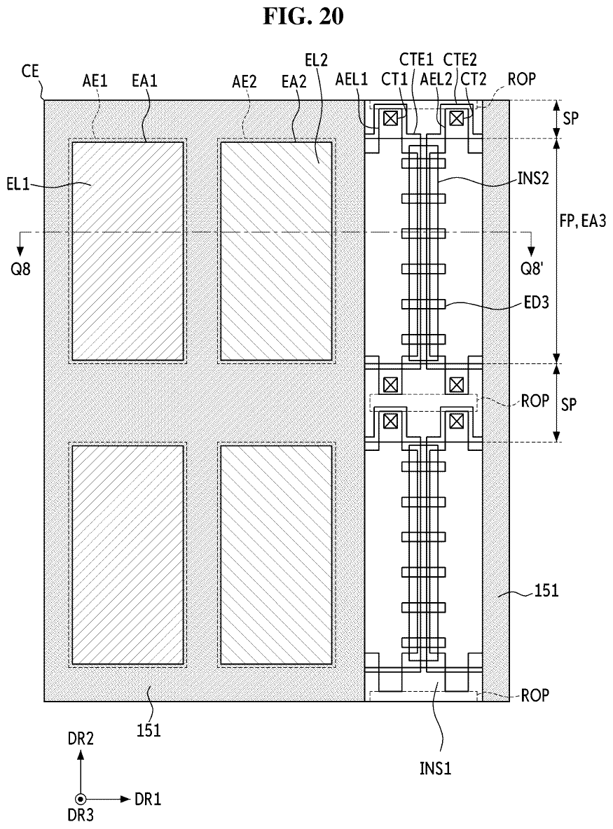

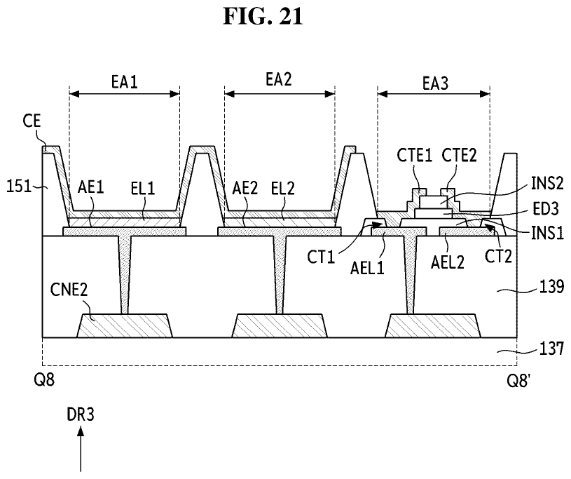

FIGS. 10 to 21 are views for each process illustrating a method for manufacturing a display device according to an embodiment. For example, FIG. 10 is a schematic plan view illustrating the formation of the first pixel electrode AE1, the second pixel electrode AE2, and the alignment electrode AEL, and FIG. 11 is a cross-sectional view taken along line Q3-Q3′ of FIG. 10. FIG. 12 is a schematic plan view illustrating the formation of the first insulating layer INS1 and the bank layer 151, and FIG. 13 is a cross-sectional view taken along line Q4-Q4′ of FIG. 12. FIG. 14 is a schematic plan view illustrating the formation of the third light emitting element ED3, and FIG. 15 is a cross-sectional view taken along line Q5-Q5′ of FIG. 14. FIG. 16 is a schematic plan view illustrating the formation of the second insulating layer INS2, and FIG. 17 is a cross-sectional view taken along line Q6-Q6′ of FIG. 16. FIG. 18 is a schematic plan view illustrating the formation of the first light emitting structure EL1 and the second light emitting structure EL2, and FIG. 19 is a cross-sectional view taken along line Q7-Q7′ of FIG. 18. FIG. 20 is a schematic plan view illustrating the formation of the common electrode CE and the contact electrode CTE, and FIG. 21 is a cross-sectional view taken along line Q8-Q8′ of FIG. 20.

First, referring to FIGS. 10 and 11, a thin film transistor layer is formed on a substrate. For example, as shown in FIG. 5, a first buffer layer 111, a lower metal layer BML, a second buffer layer 113, a thin film transistor TFT, a gate insulating layer 131, a first interlayer insulating layer 133, a capacitor electrode CPE, a second interlayer insulating layer 135, a first connection electrode CNE1, a first passivation layer 137, a second connection electrode CNE2, and a second passivation layer 139 may be sequentially formed on a substrate 110. The second passivation layer 139 may have contact holes for exposing the second connection electrode CNE2.

Next, a first pixel electrode AE1, a second pixel electrode AE2, a first alignment electrode AEL1, and a second alignment electrode AEL2 are formed on the second passivation layer 139. A masking process may be performed to form each of the electrodes.

For example, an electrode material layer may be deposited on the second passivation layer 139 and then patterned using a photolithography process to simultaneously form the first pixel electrode AE1, the second pixel electrode AE2, the first alignment electrode AEL1, and the second alignment electrode AEL2, which are patterned as shown in FIGS. 10 and 11. The first pixel electrode AE1, the second pixel electrode AE2, and the first alignment electrode AEL1 may be connected to the second connection electrode CNE2 through the contact holes through the second passivation layer 139, respectively. In some embodiments, the second alignment electrode AEL2 may be connected to a voltage line.

According to an embodiment, each of the first pixel electrode AE1 and the second pixel electrode AE2 may be formed in an island-shaped pattern corresponding to a light emission area, and each of the first alignment electrode AEL1 and the second alignment electrode AEL2 may be formed to continuously extend in the second direction DR2.

Referring to FIGS. 12 and 13, a first insulating layer INS1 and a bank layer 151 are formed.

For example, an insulating material is disposed on the second passivation layer 139, the first pixel electrode AE1, the second pixel electrode AE2, the first alignment electrode AEL1, and the second alignment electrode AEL2. Then, insulating material is patterned using a halftone mask to form the first insulating layer INS1. For example, the insulating materials disposed on the first pixel electrode AE1 and the second pixel electrode AE2 are removed. Also, a portion of the insulating material corresponding to a wide portion of the first alignment electrode AEL1 and the second alignment electrode AEL2 is formed to have a small thickness to form the first area FP of the first insulating layer INS1, and the insulating material of the other portion is formed to have a relatively large thickness to form the second area SP of the first insulating layer INS2. For example, the thickness of the second area SP may be greater than the thickness of the first area FP. In an embodiment, the thickness of the first area FP may be 40% to 60% of the thickness of the second area SP.

Next, an organic insulating material is coated and patterned on the first insulating layer INS1 to form the bank layer 151. The bank layer 151 may be formed in a grid shape to surround the first pixel electrode AE1 and the second pixel electrode AE2, and may be formed in a line shape to cover an edge of the first insulating layer INS1. Accordingly, openings of the bank layer 151 may represent the light emission areas EA1, EA2 and EA3. For example, a first light emission area EA1 may overlap the first pixel electrode AE1, a second light emission area EA2 may overlap the second pixel electrode AE2, and a third light emission area EA3 may overlap the first alignment electrode AEL1 and the second alignment electrode AEL2.

Referring to FIGS. 14 and 15, third light emitting elements ED3 are formed on the third light emission area EA3. The third light emitting elements ED3 may be arranged on the first insulating layer INS1 of the third light emission area EA3 through an inkjet printing process.

For example, when an alignment signal is applied to the first alignment electrode AEL1 and the second alignment electrode AEL2 after ink in which the third light emitting elements ED3 are dispersed is sprayed in the third light emission area EA3 partitioned by the bank layer 151, the third light emitting elements ED3 may be disposed on the first insulating layer INS1 between the first alignment electrode AEL1 and the second alignment electrode AEL2 while the position and orientation direction of the third light emitting elements ED3 in the ink are changed. Afterwards, a solvent of the ink is removed through heat treatment to form the third light emitting element ED3.

Referring to FIGS. 16 and 17, the second insulating layer INS2 is formed on the third light emitting elements ED3, and a first contact portion CT1 and a second contact portion CT2 are formed in the first insulating layer INS1.

For example, an insulating material is disposed on the third light emitting element ED3, and a photoresist pattern is formed to etch the insulating material in the area, in which the first contact portion CT1 and the second contact portion CT2 are formed. Subsequently, after the photoresist pattern is removed, a photoresist pattern is formed again to etch insulating materials in the other area except for the area overlapping the third light emitting elements ED3, thereby forming the second insulating layer INS2.

The first contact portion CT1 and the second contact portion CT2 are formed to respectively expose the first alignment electrode AEL1 and the second alignment electrode AEL2 within the second area SP of the first insulating layer INS1. The second insulating layer INS2 is formed in a shape of an island pattern extending in the second direction DR2 to cover the plurality of third light emitting elements ED3.

Referring to FIGS. 18 and 19, the first light emitting structure EL1 and the second light emitting structure EL2 are formed.

For example, the first light emitting structure EL1 and the second light emitting structure EL2 are formed on the first light emission area EA1 and the second light emission area EA2 by using an inkjet printing process. For example, the first light emitting structure EL1 may be formed on the first pixel electrode AE1 in the first light emission area EA1, and the second light emitting structure EL2 may be formed on the second pixel electrode AE2 in the second light emission area EA2. The first light emitting structure EL1 and the second light emitting structure EL2 may be formed by sequentially performing an inkjet printing process in the order of a hole injection layer, a hole transport layer, a quantum dot light emitting layer, and an electron transport layer.

Referring to FIGS. 20 and 21, a common electrode CE, a first contact electrode CTE1, and a second contact electrode CTE2 are formed.

For example, the common electrode CE is formed (e.g., continuously formed) on the first light emission area EA1 and the second light emission area EA2 by using a photolithography process after a conductive material layer is disposed on the substrate, and the first contact electrode CTE1 and the second contact electrode CTE2 are formed on the third light emission area EA3.

The common electrode CE is disposed on the first light emission area EA1 and the second light emission area EA2, and may be continuously formed. The first contact electrode CTE1 is in contact with one end portion of the third light emitting element ED3, and may be connected to the first alignment electrode AEL1 through the first contact portion CT1. The second contact electrode CTE2 is in contact with the other end portion of the third light emitting element ED3, and may be connected to the second alignment electrode AEL2 through the second contact portion CT2. As a result, the display device 10 may be manufactured. In some cases, when the material of the first contact electrode CTE1 and the second contact electrode CTE2 are the same, the material used to form the contact electrodes may be deposited in the third light emission area EA3. Then, the material is removed to form the first contact electrode CTE1 and the second contact electrode CTE2.

As described above, the method for manufacturing the display device 10 may reduce material costs by performing the ink jet printing process for the light emitting elements ED1, ED2, and ED3 in the light emission areas EA1, EA2, and EA3, respectively. Also, the common electrode CE and the contact electrodes CTE1 and CTE2 may be formed simultaneously, so that the process may be simplified and thus productivity may be increased.

Although a one-series structure in which the contact electrode CTE of the third light emission area EA3 includes the first contact electrode CTE1 and the second contact electrode CTE2 has been described as an example, the present disclosure is not necessarily limited thereto. For example, the one-series structure may represent that the light emitting elements are arranged between two contact electrodes to have one current path in the order of a first contact electrode, a light emitting element, and a second contact electrode.

In the present embodiment, a two-series structure, in which the contact electrode CTE includes three contact electrodes to have two current paths of a first current path of a first contact electrode, a first light emitting element, and a second contact electrode, and a second current path of a second contact electrode, a second light emitting element, and a third contact electrode, may be also applied.

Also, a three-series structure, in which the contact electrode CTE includes four contact electrodes to have a total of three current paths including a first current path of a first contact electrode, a first light emitting element, and a second contact electrode, a second current path of a second contact electrode, a second light emitting element, and a third contact electrode, and a third current path of a third contact electrode, a third light emitting element, and a fourth contact electrode, may be also applied.

Also, a four-series structure, in which the contact electrode CTE includes five contact electrodes to have a total of four current paths including a current path of a first contact electrode, a first light emitting element, and a second contact electrode, a second current path of a second contact electrode, a second light emitting element, and a third contact electrode, a third current path of a third contact electrode, a third light emitting element, and a fourth contact electrode, and a fourth current path of a fourth contact electrode, a fourth light emitting element, and a fifth contact electrode, may be also applied.

In the detailed description, those skilled in the art will appreciate that many variations and modifications can be made to the preferred embodiments without substantially departing from the technical scope and principles of the present inventive concept. Therefore, the disclosed preferred embodiments of the invention are used in a generic and descriptive sense.

What is claimed is:

1. A display device comprising:
a substrate including a first light emission area, a second light emission area, and a third light emission area;
a first pixel electrode disposed in the first light emission area;
a second pixel electrode disposed in the second light emission area;
alignment electrodes disposed in the third light emission area;
first and second light emitting structures disposed on the first and second pixel electrodes, respectively, wherein each of the first and second light emitting structures includes a quantum dot light emitting layer;
an inorganic light emitting diode disposed on the alignment electrodes;
a common electrode disposed on the first and second light emitting structures; and
a first contact electrode and a second contact electrode disposed on the inorganic light emitting diode, wherein the first contact electrode contacts one end portion of the inorganic light emitting diode and the second contact electrode contacts other end portion of the inorganic light emitting diode.

2. The display device of claim 1, wherein: the first pixel electrode, the first light emitting structure, and the common electrode are disposed in the first light emission area, and
the second pixel electrode, the second light emitting structure, and the common electrode are disposed in the second light emission area.

3. The display device of claim 2, wherein:
the common electrode is continuously extended and disposed in the first light emission area and the second light emission area.

4. The display device of claim 2, wherein:
the first light emission area emits red light, the second light emission area emits green light, and the third light emission area emits blue light.

5. The display device of claim 2, further comprising:
a first insulating layer disposed on the alignment electrodes,
wherein the alignment electrodes include first and second alignment electrodes spaced apart from each other, and
the inorganic light emitting diode is disposed on the first insulating layer and overlaps at least a portion of the first alignment electrode and a portion of the second alignment electrode.

6. The display device of claim 5, further comprising:
a second insulating layer disposed on the inorganic light emitting diode,
wherein the second insulating layer has an island-shaped pattern.

7. The display device of claim 6, wherein:
the first insulating layer and the second insulating layer overlap the third light emission area and do not overlap the first light emission area and the second light emission area.

8. The display device of claim 5, wherein:
the first insulating layer includes a first area overlapping the inorganic light emitting diode and a second area adjacent to the first area, and
a thickness of the first insulating layer in the first area is smaller than a thickness of the first insulating layer in the second area.

9. The display device of claim 1, wherein:
the first pixel electrode, the second pixel electrode, and the alignment electrodes are disposed at a same layer, and the first pixel electrode, the second pixel electrode, and the alignment electrodes include a same material.

10. The display device of claim 1, wherein:
the common electrode, the first contact electrode, and the second contact electrode include a same material.

11. A method for manufacturing a display device, the method comprising:
forming a first pixel electrode, a second pixel electrode, and alignment electrodes on a substrate;
forming a first insulating layer on the alignment electrodes;
forming a bank layer on the first insulating layer, the first pixel electrode, and the second pixel electrode to partition the first pixel electrode, the second pixel electrode, and the alignment electrodes;
forming an inorganic light emitting diode on the alignment electrodes;
forming a second insulating layer on the inorganic light emitting diode;
forming a first light emitting structure on the first pixel electrode and forming a second light emitting structure on the second pixel electrode; and
forming a common electrode on the first light emitting structure and the second light emitting structure, and simultaneously forming a first contact electrode contacting one end of the inorganic light emitting diode and a second contact electrode contacting other end of the inorganic light emitting diode on the second insulating layer.

12. The method of claim 11, wherein:
the first pixel electrode, the second pixel electrode, and the alignment electrodes are formed simultaneously.

13. The method of claim 11, wherein:
the first insulating layer is formed to include a first area and a second area thicker than the first area by using a halftone mask.

14. The method of claim 11, wherein:
each of the inorganic light emitting diode, the first light emitting structure, and the second light emitting structure is formed using an inkjet printing process.

15. The method of claim 11, wherein forming the second insulating layer comprises:
forming contact holes to expose the alignment electrodes by etching a portion of the first insulating layer.

16. The method of claim 15, wherein:
the first contact electrode and the second contact electrode are connected to the alignment electrodes through the contact holes.

17. An electronic device, comprising:
a display device;
a memory having a stored application for operating the electronic device including the display device;
a processor configured to execute the application stored in the memory; and
a power module configured to supply power to the display device, the memory, and the processor,
wherein the display device includes:
a substrate including a first light emission area, a second light emission area, and a third light emission area;
a first pixel electrode disposed in the first light emission area;
a second pixel electrode disposed in the second light emission area;
alignment electrodes disposed in the third light emission are;
first and second light emitting structures disposed on the first and second pixel electrodes, respectively, wherein each of the first and second light emitting structures includes a quantum dot light emitting layer;
an inorganic light emitting diode disposed on the alignment electrodes;
a common electrode disposed on the first and second light emitting structures; and
a first contact electrode and a second contact electrode disposed on the inorganic light emitting diode, wherein the first contact electrode contacts one end portion of the inorganic light emitting diode and the second contact electrode contacts other end portion of the inorganic light emitting diode.

18. The electronic device of claim 17, wherein:
the first pixel electrode, the second pixel electrode; and the alignment electrodes are disposed at a same layer, and the first pixel electrode, the second pixel electrode, and the alignment electrodes include a same material.

19. The electronic device of claim 17, wherein:
the common electrode, the first contact electrode, and the second contact electrode include a same material.

20. The electronic device of claim 17, wherein:
the first light emission area emits red light, the second light emission area emits green light, and the third light emission area emits blue light.
